(19) United States
(12) Patent Application Publication
(10) Pub. No.: US 2011/0233521 A1
(43) Pub. Date: Sep. 29, 2011

(54) SEMICONDUCTOR WITH CONTOURED STRUCTURE

(75) Inventor: Adam William Saxler, Durham, NC (US)

(73) Assignee: CREE, INC., Durham, NC (US)

(21) Appl. No.: 12/730,904

(22) Filed: Mar. 24, 2010

(51) Int. Cl. H01L 29/66; H01L 29/06; H01L 21/20

(52) U.S. Cl. 257/24; 257/618; 438/488; 257/E29.168; 257/E29.005; 257/E21.09

(57) ABSTRACT

The present disclosure relates to a semiconductor device that has a first semiconductor structure that is grown to form a non-planar growth surface. The non-planar growth surface is formed from multiple facets and provides a defined contour. The defined contour may include, but is not limited to a corrugated contour or a pyramidal contour. A second semiconductor structure is grown over the non-planar growth surface of the first semiconductor structure, and as such, the second semiconductor structure is non-planar and follows the defined contour of the non-planar growth surface of the first semiconductor structure. The first and second semiconductor structures may form the foundation for various types of electrical and optoelectrical semiconductor devices, such as diodes, transistors, thyristors, and the like.

### FIELD OF THE DISCLOSURE

The present disclosure is related to semiconductors, and in particular to a semiconductor having a contoured epitaxial structure.

### BACKGROUND

Semiconductor based optoelectronic devices, such as light emitting diodes and laser diodes, convert electrical energy into light. These optoelectronic devices are diodes that produce energy in the form of light when current passes the p-n junctions of the diodes. As current passes the p-n junction, electrons that have been excited from a valence band into a conduction band will fall back into an available empty state of a valence band. This empty state is commonly referred to as a hole, and the process of an electron combining with an available hole is referred to as recombination. The process of recombination is generally associated with electrons moving from a higher energy state in the conduction band to a lower energy state in the valence band, and as such, energy is released as the electrons return to the lower energy state. When the optoelectronic device is formed from certain materials, the energy is released in the form of photons, or emitted light. The type of material used to form the optoelectronic device will generally control the wavelength associated with the emitted light.

In an effort to improve the efficiency of recombination, and thus the efficiency with which light is generated, modern optoelectronic devices employ the use of one or more quantum wells at or near the p-n junction to effectively confine high concentrations of electrons and holes in a substantially two dimensional planar region along the p-n junction. Increasing the concentrations of electrons and holes along the same planar region tends to increase the efficiency with which electrons and holes combine. An exemplary optoelectronic device that employs one or more quantum wells is illustrated in FIG. 1.

As depicted, an optoelectronic device 10, such as a light emitting diode or laser diode, is formed by creating a diode structure 12 where a planar active structure 14 is sandwiched between a planar p-type structure 16 and a planar n-type structure 18. One or more planar quantum wells are formed in the active structure 14, such that the planar quantum wells are substantially parallel to one another as well as to the p-type structure 16 and the n-type structure 18. Each of these respective structures may be formed from one or more epitaxial layers of the same or different semiconductor material, wherein each layer is successively grown over an appropriate substrate 20. Further, ohmic contacts may be formed to facilitate electrical connection to both the p-type structure and the n-type structure. As illustrated, a p-contact 22 is provided on the p-type structure 16 while an n-contact 24 may be provided on the n-type structure 18 or on the substrate 20, if the substrate is a non-insulating substrate.

A commercially viable semiconductor material system used to make optoelectronic devices is the group III nitride material system. Compounds formed at least in part from a group III element and group V element of the periodic table of elements are referred to as a group III-V compounds. When the group V element of the group III-V compound is nitrogen, the resulting compound is referred to as a group III nitride compound. Group III nitride compounds are prominently used in the semiconductor industry to make optoelectronic devices that generally operate in the green, blue, and ultraviolet (UV) spectra as well as high frequency electronic devices, such as field effect transistors (FETs) and diodes. Among others, common group III nitride compounds include gallium nitride (GaN), aluminum nitride (AlN), indium nitride (InN), aluminum gallium nitride (AlGaN), and indium gallium nitride (InGaN). Of the different group III nitride-based optoelectronic devices, GaN-based optoelectronic devices have proven to be particularly commercially successful, and efforts continue to improve the light emitting efficiency and quality of these devices.

However, an impediment to improving the light emitting efficiency of GaN-based devices revolves around the GaN crystalline structure, and in particular, the inherent electric fields that naturally occur in this type of crystalline structure. With reference to FIG. 2A, GaN generally takes on a wurtzite crystalline structure, which is hexagonal in nature. The gallium ions are represented by the larger spheres, whereas the nitrogen ions are represented by the smaller spheres. As is evident from the illustration, the wurtzite crystalline structure lacks vertical symmetry along the c-axis. This lack of symmetry causes the crystalline structure to be polarized along the c-axis, and as a result, the c-planes, which are normal to the c-axis, are polarized. As one proceeds from one c-plane to the next along the c-axis, each plane will contain either gallium ions or nitrogen ions, but never both gallium ions and nitrogen ions. For example, the c-plane (0001) that is highlighted in FIG. 2B is polarized because it only includes gallium ions and does not contain any nitrogen ions. Accordingly, adjacent c-planes will generally have opposing polarities. To maintain overall charge neutrality in light of this lack of symmetry, a GaN crystal will have one end that terminates with a first c-plane face that contains only gallium ions and a second c-plane face that contains only nitrogen ions. Polarization that is caused by this lack of crystalline symmetry along a given axis is generally referred to as spontaneous polarization.

Another type of polarization is caused by the strain induced by the lattice mismatch at the junction of epitaxial layers of different group III nitride compounds. Such polarization is referred to as piezoelectric polarization. The cumulative effect of the ever present spontaneous and piezoelectric polarization creates significant electric fields within the crystalline structure, and these electric fields can negatively impact light emitting efficiency. The impact of the electric fields is most problematic for group III nitride optoelectronic devices that are grown along the c-axis [0001] where the resulting polarized c-planes are perpendicular to the c-axis [0001] and coincide with the planar quantum wells in the active structure 14. This c-axis crystalline orientation essentially aligns the electric fields of the c-planes along each quantum well. In the active structure 14, aligning the electric fields along the quantum wells in this manner tends to separate the electrons and holes within the quantum wells, and therefore decreases the recombination efficiency of the electrons and holes. In essence, aligning the quantum wells normal to the c-axis (or in parallel with the c-plane) of a c-oriented active structure 14 limits the potential effectiveness of the quantum wells in facilitating recombination. The result is reduced light emitting efficiency of the optoelectronic device 10 and unwanted shifts in the wavelength of emitted light.

Unfortunately, most commercially viable fabrication techniques for growing group III nitride optoelectronic devices employ growth techniques along the c-axis in the [0001] direction, thereby forcing designers to cope with the inherent presence of electric fields along the quantum wells in optoelectronic devices having c-oriented crystalline structures. Accordingly, there is a need for an optoelectronic device structure that can take advantage of commercially available growth techniques while reducing the negative impact that electric fields, such as those caused by spontaneous or piezoelectric polarization, have on light emitting efficiency.

### SUMMARY OF THE DETAILED DESCRIPTION

The present disclosure relates to a semiconductor device that has a first semiconductor structure that is grown to form a non-planar growth surface. The non-planar growth surface is formed from multiple facets and provides a defined contour. The defined contour may include, but is not limited to a corrugated contour or a pyramidal contour. A second semiconductor structure is grown over the non-planar growth surface of the first semiconductor structure, and as such, the second semiconductor structure is non-planar and follows the defined contour of the non-planar growth surface of the first semiconductor structure. The first and second semiconductor structures may form the foundation for various types of electrical and optoelectrical semiconductor devices, such as diodes (including light emitting diodes and laser diodes), transistors, thyristors, and the like.

In one optoelectronic device embodiment, the second semiconductor structure is an active structure and is formed between the first semiconductor structure of a first conductive type and a third semiconductor structure of a second conductive type. The second semiconductor structure provides one or more quantum wells therein. Since the second semiconductor structure is non-planar, portions of quantum wells within or around the second semiconductor structure can be electively oriented along crystalline planes that are associated with desired polarizations. Orientations along crystalline planes that are associated with undesired polarizations can be avoided. Controlling the orientation of the different portions of the second semiconductor structure in this manner allows control of the type of polarization that is imparted to the quantum wells during operation of the semiconductor device.

For reference, each plane and directions normal to this plane in a crystalline structure are associated with a given polarization. Available polarizations include polar, semi-polar, and non-polar polarizations. As such, a polar plane and a direction normal to the polar plane are associated with a polar polarization. Similarly, a semi-polar plane and a direction normal to the semi-polar plane are associated with a semi-polar polarization.

In this embodiment, the first semiconductor structure has a first crystalline orientation that is associated with a first polarization along a primary growth direction. The primary growth direction is the overall or general direction of epitaxial growth for the semiconductor device. The first semiconductor structure is grown to have a non-planar growth surface, which is formed from crystalline facets and provides a defined contour. At least some of these facets provide corresponding growth planes that are associated with at least one polarization that is different than the first polarization.

The second semiconductor structure is grown over the non-planar growth surface. Portions of the second semiconductor structure may also be grown over the growth planes and have secondary growth directions that are substantially normal to the growth planes. These portions of the second semiconductor structure may also be associated with the at least one polarization that is different than the first polarization. A third semiconductor structure is grown over the second semiconductor structure, and appropriate contacts may be provided to facilitate the appropriate electrical connections to one or more of the semiconductor structures.

For the above embodiment, if the first crystalline orientation is a polar (c-oriented) crystalline orientation and the primary growth direction is along the polar c-axis of the first crystalline structure, the crystalline facets that form the non-planar growth surface of the first semiconductor structure may reside on one or more semi-polar planes, non-polar planes, or a combination thereof. As a result, the direction of growth for those portions of the second semiconductor structure that are grown on the growth planes provided by the crystalline facets are not grown in a polar direction. Instead, those portions of the second semiconductor structure are grown in a corresponding semi-polar or non-polar direction.

In this example, since portions of the non-planar second semiconductor structure are grown in semi-polar or non-polar directions, the quantum wells provided by these portions of the second semiconductor structure will reside along semi-polar or non-polar planes. When residing along semi-polar or non-polar planes, quantum wells are impacted less by the electric fields caused by spontaneous and piezoelectric polarization within the crystalline structure than if the portions of the quantum wells were oriented along a polar plane. Accordingly, the quantum wells in non-planar second semiconductor structures of the present disclosure are not subjected to electric fields to the same extent as quantum wells that reside in planar second semiconductor structures. In optoelectronic devices, reducing the impact of these electric fields improves light emitting efficiency and provides better control over the wavelength of emitted light. As noted, the concepts disclosed herein are applicable to other types of semiconductor devices, such as diodes, transistors, thyristors, and the like.

Those skilled in the art will appreciate the scope of the present disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure, and together with the description serve to explain the principles of the disclosure.

FIG. 1 is a cross-section of an optoelectronic semiconductor device according to the prior art.

FIG. 2A is a wurtzite crystalline structure for a GaN crystalline structure.

FIG. 2B illustrates a polar c-plane (0001) in the GaN crystalline structure.

FIG. 3A illustrates a non-polar a-plane (11 2̅0) in the GaN crystalline structure.

FIG. 3B illustrates a non-polar m-plane (1 1̅00) in the GaN crystalline structure.

FIG. 4A illustrates a semi-polar r-plane (10 1̅2) in the GaN crystalline structure.

FIG. 4B illustrates a semi-polar plane (11 2̅2) in the GaN crystalline structure.

FIG. 5 is a cross-section of an optoelectronic semiconductor device according to a first embodiment of the disclosure.

FIG. 6A is a perspective view of an optoelectronic semiconductor device that has a corrugated contour according to an embodiment of the disclosure.

FIG. 6B is a perspective view of an optoelectronic semiconductor device that has a contour of a pyramidal array according to an embodiment of the disclosure.

FIG. 6C is a top view of an optoelectronic semiconductor device that has a contour of a pyramidal array according to an embodiment of the disclosure.

FIG. 7A is a cross-section of an optoelectronic semiconductor device that employs current masks over select portions of an active structure according to an embodiment of the disclosure.

FIG. 7B is a cross-section of an optoelectronic semiconductor device that employs implants in select portions of an active structure according to an embodiment of the disclosure.

FIG. 8 is a cross-section of an optoelectronic semiconductor device that employs recesses in select portions of an active structure according to an embodiment of the disclosure.

FIG. 9 is a cross-section of an optoelectronic semiconductor device according to a second embodiment of the disclosure.

FIG. 10 is a cross-section of an optoelectronic semiconductor device according to a third embodiment of the disclosure.

FIG. 11 is a cross-section of an optoelectronic semiconductor device according to a fourth embodiment of the disclosure.

FIG. 12 is a more detailed cross-section of an optoelectronic semiconductor device that is fabricated on a non-insulating substrate according to an embodiment of the disclosure.

FIG. 13 is a more detailed cross-section of an optoelectronic semiconductor device that is fabricated on an insulating substrate according to an embodiment of the disclosure.

FIG. 14 is a cross-section of an optoelectronic semiconductor device that employs a patterned conversion mask that is configured to alter subsequent epitaxial growth such that a non-planar growth surface of a defined contour is formed on the n-type structure according to an embodiment of the disclosure.

FIG. 15 is a cross-section of an optoelectronic semiconductor device that employs a pattern of conversion recesses that is configured to alter subsequent epitaxial growth such that a non-planar growth surface of a defined contour is formed on the n-type structure according to an embodiment of the disclosure.

FIG. 16 is a cross-section of an optoelectronic semiconductor device that includes a contact layer having a planar top surface according to an embodiment of the disclosure.

FIG. 17 is a cross-section of an optoelectronic semiconductor device that includes a p-type structure having a planar top surface according to an embodiment of the disclosure.

FIG. 18 is a cross-section of an optoelectronic semiconductor device that includes multiple contoured sections according to an embodiment of the disclosure.

FIG. 19 is a cross-section of a high electron mobility transistor according to an embodiment of the disclosure.

### DETAILED DESCRIPTION

The embodiments set forth below represent the necessary information to enable those skilled in the art to practice the disclosure and illustrate the best mode of practicing the disclosure. Upon reading the following description in light of the accompanying drawings, those skilled in the art will understand the concepts of the disclosure and will recognize applications of these concepts not particularly addressed herein. It should be understood that these concepts and applications fall within the scope of the disclosure and the accompanying claims. When an element such as a layer, sublayer, structure, portion, region or substrate is referred to as being “on” or extending “onto” another element, it can be directly on or extend directly onto the other element, or intervening elements may also be provided. In contrast, if an element is referred to as being “directly on” or extending “directly onto” another element, there are no intervening elements present. Further, complementary conductivity configurations are available for each embodiment.

The following disclosure often refers to a hexagonal coordinate system to identify planes and directions relative to the hexagonal wurtzite crystalline structures of various group III nitride compounds, such as GaN, AlN, AlGaN, and InGaN. Reference to GaN or other group III nitride compounds and the hexagonal coordinate system is intended merely to provide practical examples of the various embodiments described herein and should in no way limit the scope of the disclosure. The principles and concepts provided extend to other material systems, such as the gallium arsenide (GaAs) or zinc oxide (ZnO) material systems, that are fabricated using polarized crystalline structures.

Further, reference to a particular compound is considered to include the primary compound as well as any ternary, quaternary, or other compounds of the primary compound. For example, reference to a GaN-based compound or structure is considered to include GaN as well as any of its ternary and quaternary compounds, such as, but not limited to aluminum and indium. As such, a GaN-based compound or structure may include any combination of GaN, AlGaN, or InGaN epitaxial layers. Further, compounds from different material systems may be included in a given structure. For example, a GaN structure may include one or more layers of AlInGaN, BAlInGaNPAsSb, or the like; a GaAs structure may include one or more layers of AlInGaAsP, GaInAsSb, or the like; and a ZnO structure may include one or more layers of MgZnCaO.

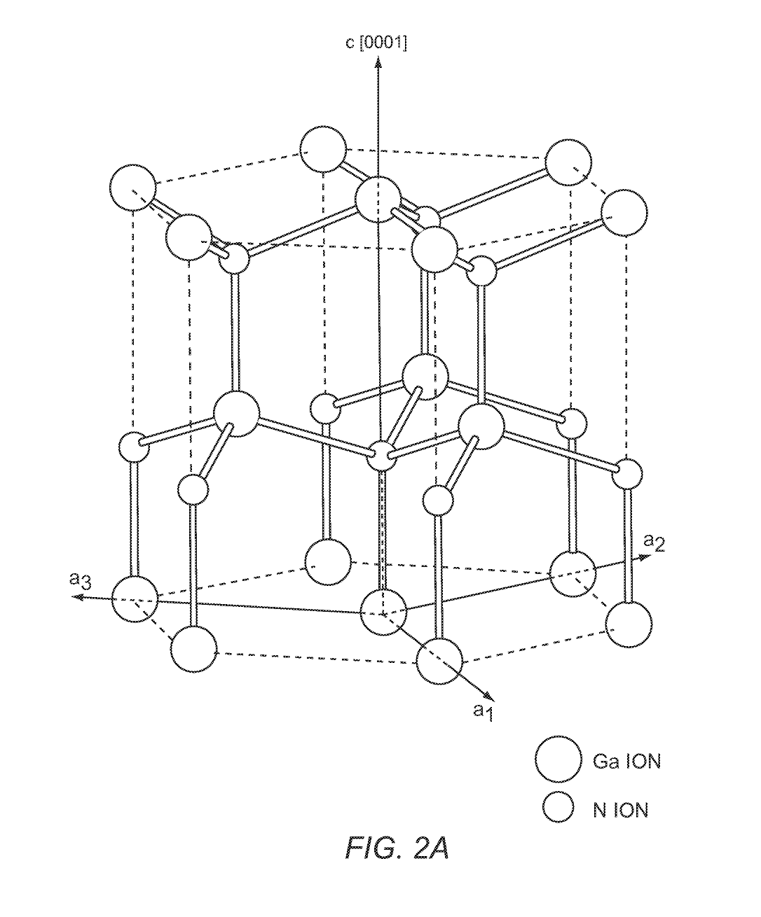

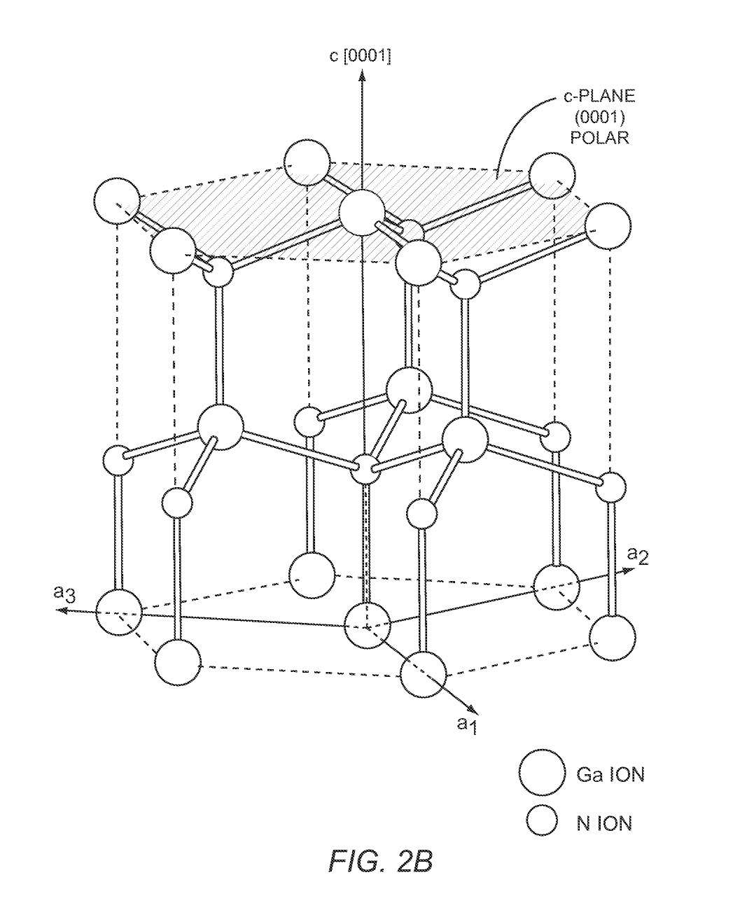

With reference to FIG. 2A, the wurtzite crystalline structure of a GaN crystalline structure is depicted in association with the four axes of a hexagonal coordinate system. These axes include three basal plane a-axes (a1, a2, a3), which are rotated 120° with respect to one another, and a c-axis, which is normal to each of the a-axes. As illustrated, the c-axis runs vertically through the center of the GaN crystalline structure. Given the polarized nature of the GaN crystalline structure, polar, non-polar, and semi-polar planes are found in the crystalline structure. These planes exist for other group III nitride compounds as well as for any semiconductor material that takes on a polarized crystalline structure of virtually any geometry.

As previously described, the GaN crystalline structure is polar in nature. Proceeding from plane to plane along the polar c-axis, the GaN crystalline structure will contain either gallium ions or nitrogen ions, but never both. In essence, planes with gallium ions alternate with planes with nitrogen ions. As such, these planes are each associated with a polarity and are referred to as polar planes. Since these polar planes are normal to the c-axis, they are generally referenced as c-planes. To maintain charge neutrality for a given GaN crystal, each GaN crystal will terminate with one c-face that only includes gallium ions and an opposing c-face that only includes nitrogen ions. FIG. 2B illustrates a terminating c-plane (0001), which is inherently polarized and includes only gallium ions, in a GaN crystalline structure.

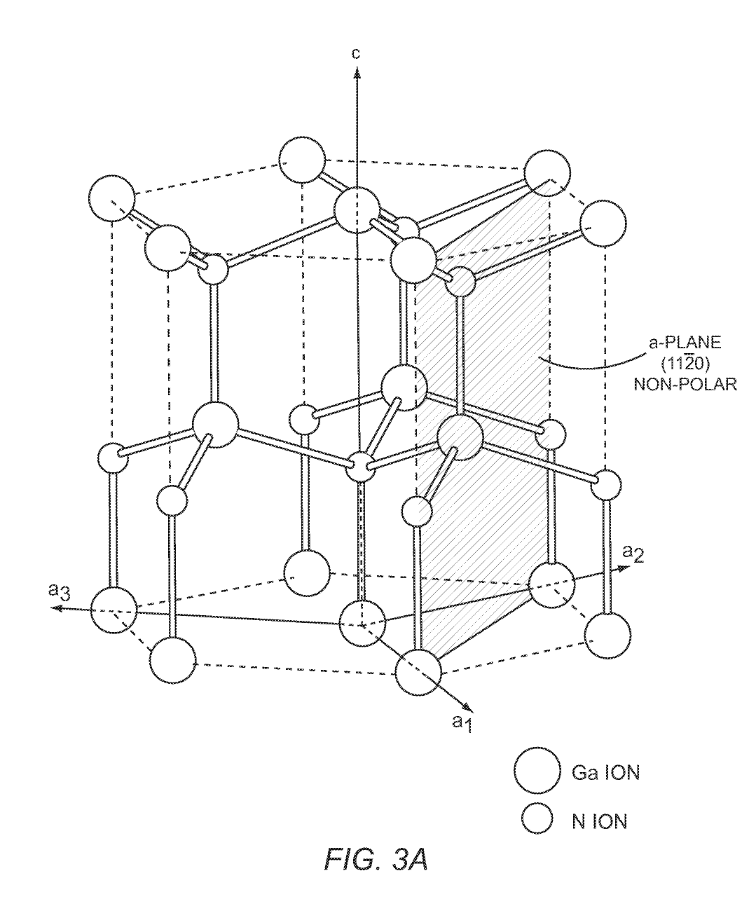

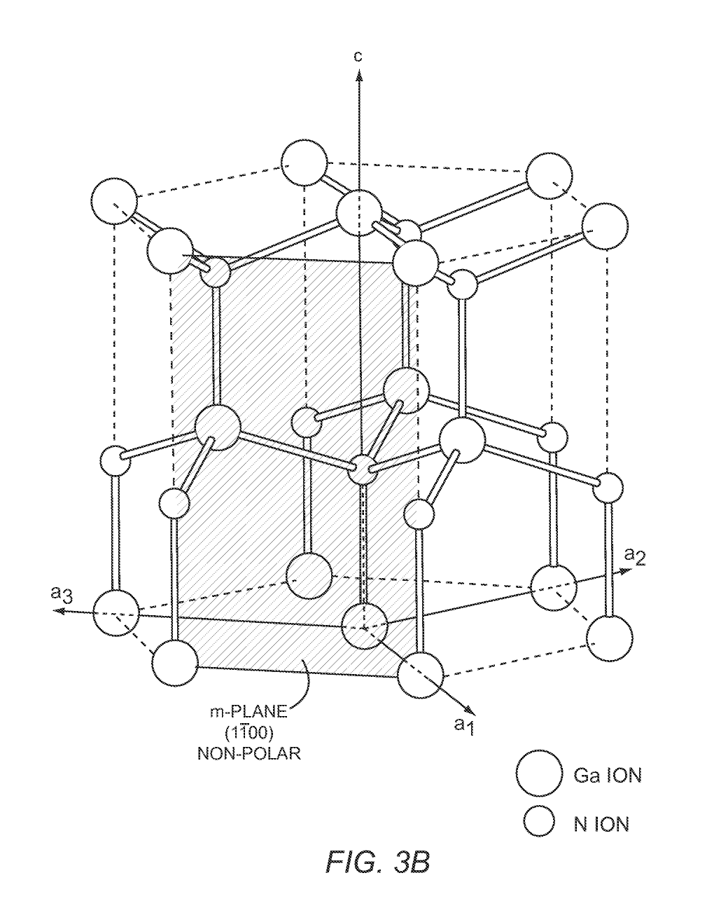

Unlike polar planes, non-polar planes are charge neutral and will include both gallium ions and nitrogen ions. In a GaN crystalline structure, non-polar planes will essentially include an equal number of gallium ions and nitrogen ions. Non-polar planes are generally parallel to the c-axis and normal to the c-planes. FIGS. 3A and 3B illustrate two exemplary non-polar planes in a GaN crystalline structure. FIG. 3A provides a (11 2̅0) non-polar plane that is commonly referred to as an a-plane. FIG. 3B provides a (1 1̅00) non-polar plane that is commonly referred to as an m-plane.

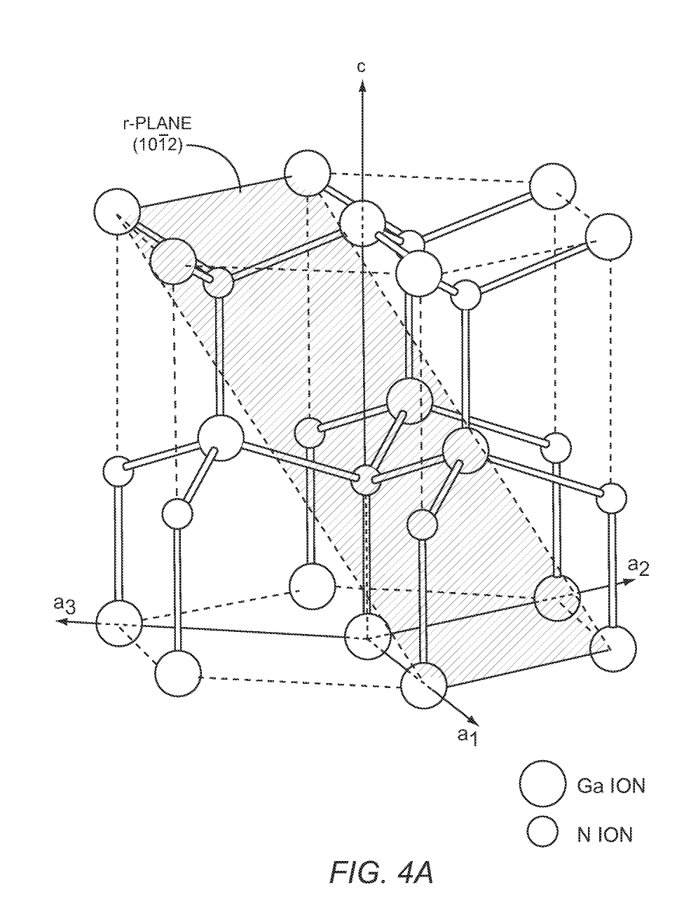

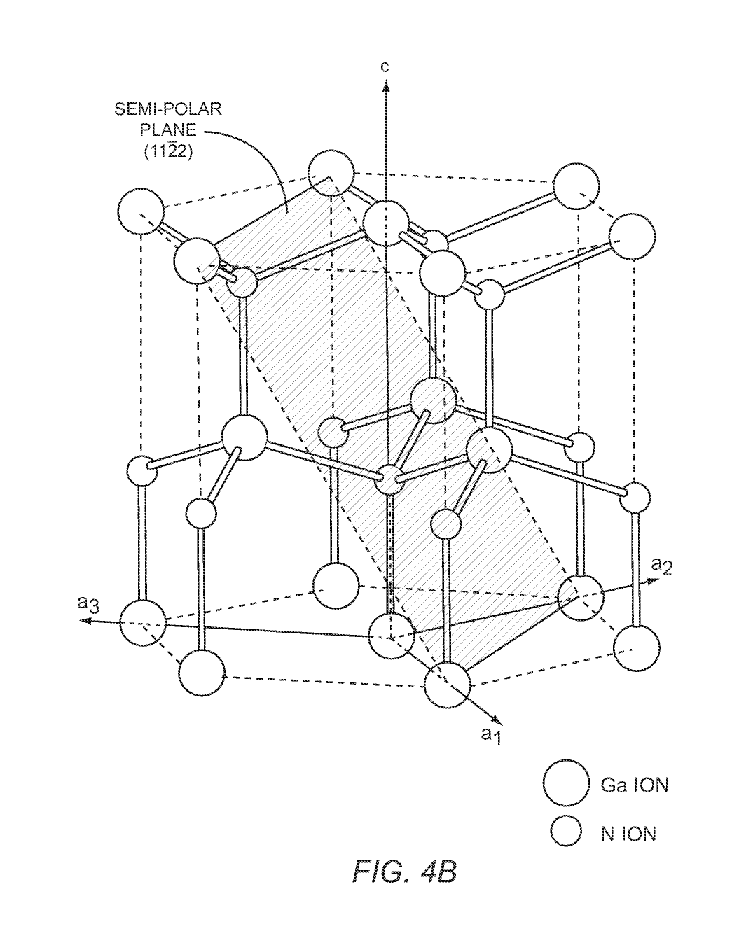

Semi-polar planes fall somewhere between polar and non-polar planes. Technically, a semi-polar plane refers to any of a variety of planes that have two nonzero h, i, or k Miller indices and a nonzero I Miller index. Examples of semi-polar planes in the GaN crystalline structure include, but are not limited to those found in the following families: {11 2̅2}, {10 1̅1}, {10 1̅3}, {10 1̅2}, {20 2̅1}, and {10 1̅4}. Although semi-polar planes are polarized to an extent, the magnitude of such polarization is less than that of a polarized (c-) plane. Semi-polar planes generally form an angle with respect to a c-plane that is between 15° and 75°. For example, the (10 1̅1) and (10 1̅3) planes are at 62.98° and 32.06° with respect to the c-plane, respectively. FIGS. 4A and 4B illustrate two exemplary semi-polar planes in a GaN crystalline structure. FIG. 4A provides a (10 1̅2) semi-polar plane that is commonly referred to as an r-plane. FIG. 4B provides a (11 2̅2) semi-polar plane. Although specific polar, non-polar, and semi-polar planes are identified and discussed above, the discussion or identification of any particular plane is considered to include all the planes in the family of planes in which the particular plane resides. For example, the discussion of the (11 2̅2) semi-polar plane naturally extends to include all of the planes in the {11 2̅2} family of planes.

Polar, non-polar, and semi-polar directions are considered to include all directions within about 10° of theoretical polar, non-polar, and semi-polar directions, respectively. Similarly, polar, non-polar, and semi-polar planes and orientations share the same 10° of tolerance. Such latitude is necessary to accommodate imperfections in materials, natural crystalline growth, and the like. A plane associated with a particular polarization will correspond to a direction that is normal to the plane. The polarization associated with the direction and corresponding plane will be the same. Although the initial embodiments described below relate to optoelectronic devices, the concepts disclosed herein are applicable to other types of semiconductor devices, such as diodes, transistors, thyristors, and the like. In particular, a high electron mobility transistor (HEMT) configuration is provided further below.

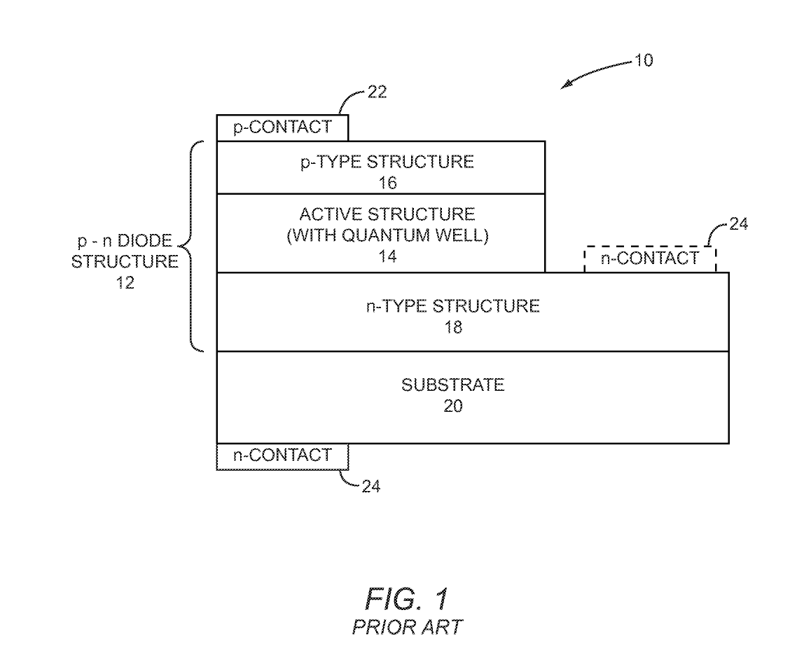

As described earlier with reference to FIG. 1, a conventional optoelectronic device 10 employs a planar active structure 14 with one or more quantum wells sandwiched between a planar p-type structure 16 and a planar n-type structure 18. Given the planar nature of the active structure 14, the quantum wells provided therein are also planar. Due to the relative ease of fabrication, the epitaxial layers of GaN-based semiconductors are generally grown parallel to the c-axis. As such, these epitaxial layers, including those used to form the active structure 14 and the quantum wells therein, generally run parallel to the polarized c-planes of the c-oriented epitaxial structure. When the planar quantum wells are aligned parallel to the polarized c-planes, the aforementioned electric fields that are associated with the c-planes hinder the function of the quantum wells by separating the electrons and holes, reducing recombination efficiency, and red-shifting the wavelength of emitted light.

For a first embodiment, the present disclosure includes techniques for forming a non-planar active structure in an optoelectronic device, such that at least desired portions of the quantum wells in these non-planar active structures are not parallel to any polar planes in the associated crystalline structure. Instead, the desired portions of the quantum wells are formed along semi-polar planes, non-polar planes, or a combination thereof. By forming the quantum wells such that they are not parallel to the polar planes, the impact that the electric fields from the polar planes have on the quantum wells is significantly reduced, if not eliminated. As a result, light emitting efficiency increases, because the electron and hole distribution in the quantum well is increased and recombination efficiency increases. Further, the wavelength of emitted light is not unnecessarily shifted. For example, the wavelength of emitted light is not undesirably shifted toward the red portion of the light spectrum.

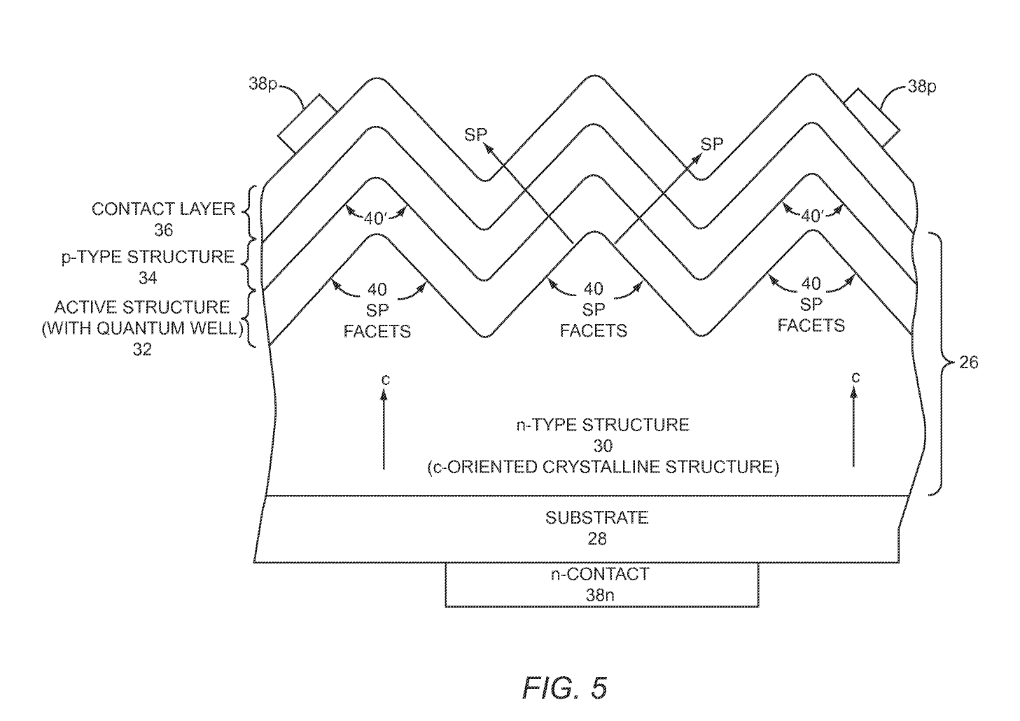

A cross-section of an optoelectronic device that employs such techniques is illustrated in FIG. 5. As those skilled in the art will recognize, the epitaxial structure of the overall optoelectronic device as well as the identified structures may include numerous epitaxial layers and features that are not specifically identified or shown. More detailed epitaxial structures for exemplary optoelectronic devices are described later on in the disclosure. As illustrated, the optoelectronic device has a diode structure 26 that is formed on an appropriate substrate 28. The diode structure 26 includes an n-type structure 30, an active structure 32, a p-type structure 34, and a contact layer 36. First ohmic contacts, which are referred to as p-contacts 38p, are provided on the contact layer 36. A second ohmic contact, which is referred to as an n-contact 38n, is provided on a side of the substrate 28 opposite the diode structure 26. As illustrated further below, the n-contact 38n may alternately be provided on the n-type structure 30.

In this example, assume that the n-type structure 30 has a c-oriented crystalline structure, which indicates that the n-type structure 30 was mostly grown parallel to the c-axis, and as such, will have polarized c-planes parallel to the general plane of the substrate 28. Through techniques to be later described, the n-type structure 30 is grown such that the top surface provides a non-planar growth surface, which is formed from crystalline facets and has a defined contour. These crystalline facets are formed along one or more semi-polar planes and are referred to as semi-polar (SP) facets 40.

Each semi-polar facet 40 provides a semi-polar growth plane, and collectively, the semi-polar facets 40 form a non-planar growth surface on which the active structure 32 is grown. The epitaxial layers of the active structure 32 are successively grown on the non-planar growth surface of the n-type structure 30. As a result, the active structure 32 follows the defined contour of the non-planar growth surface of the n-type structure 30. In particular, corresponding portions of the epitaxial layers of the active structure 32 are successively grown in one or more semi-polar (SP) directions on the respective semi-polar facets 40 of the non-planar growth surface. The epitaxial layers of the active structure 32 will be parallel to the corresponding growth facets 40, and thus will be parallel to semi-polar planes. Accordingly, the quantum wells that are provided by certain of the epitaxial layers of the active structure 32 will be parallel to a semi-polar plane instead of any polar c-planes.

By forming the quantum wells parallel to a semi-polar plane instead of a polar plane, the electric fields along the polar planes have significantly reduced impact on the functionality of the quantum well. As such, light emitting efficiency increases due to increased recombination efficiency, and shifting of emitted light is decreased. An additional benefit of the embodiment disclosed in FIG. 5 is the substantial increase in surface area covered by the non-planar active structure 32. Depending on the angle of the semi-polar facets 40, the amount of surface area can exceed twice that of the planar active structure 14 shown in FIG. 1. This increase in surface area of the active structure 32 directly corresponds to an increase in the surface area of the optoelectronic device that is capable of emitting light. Coupling the increased light emitting surface area with the light emitting efficiencies gained by aligning the quantum well along a semi-polar plane provides significant light output and efficiency gains over traditional configurations.

Once the active structure 32 is formed, the top surface of the active structure 32 will essentially mimic the defined contour of the n-type structure 30, and as such will provide another semi-polar growth surface of semi-polar facets 40′ for the p-type structure 34. The epitaxial layers of the p-type structure 34 and the contact layer 36 are successively grown on the non-planar growth surface of the active structure 32. As a result, the p-type structure 34 may follow the defined contour of the non-planar growth surface of the active structure 32. In particular, corresponding portions of the epitaxial layers of the p-type structure 34 are successively grown in the one or more semi-polar directions on the respective semi-polar facets 40′. The epitaxial layers of the p-type structure 34 may be parallel to the corresponding growth facets 40 and 40′, and thus will be parallel to semi-polar planes. One or more of the p-contacts 38p may be formed on the top surface of the p-type structure 34. Although growth directions may change, the crystalline orientation for each structure may remain substantially the same.

In a GaN or other group III nitride based optoelectronic device with a substantially c-oriented crystalline structure, the various growth facets 40 that form the non-planar growth surface on the top surface of the n-type material may be formed along one or more semi-polar planes. These growth facets 40 are angled with respect to the overall plane of the substrate 28 as well as with respect to the polar c-planes of the c-oriented crystalline structure. These semi-polar planes may include, but are not limited to, those planes that reside along planes in the {11 2̅2}, {10 1̅1}, {10 1̅3}, {10 1̅2}, {20 2̅1}, and {10 1̅4} families of planes.

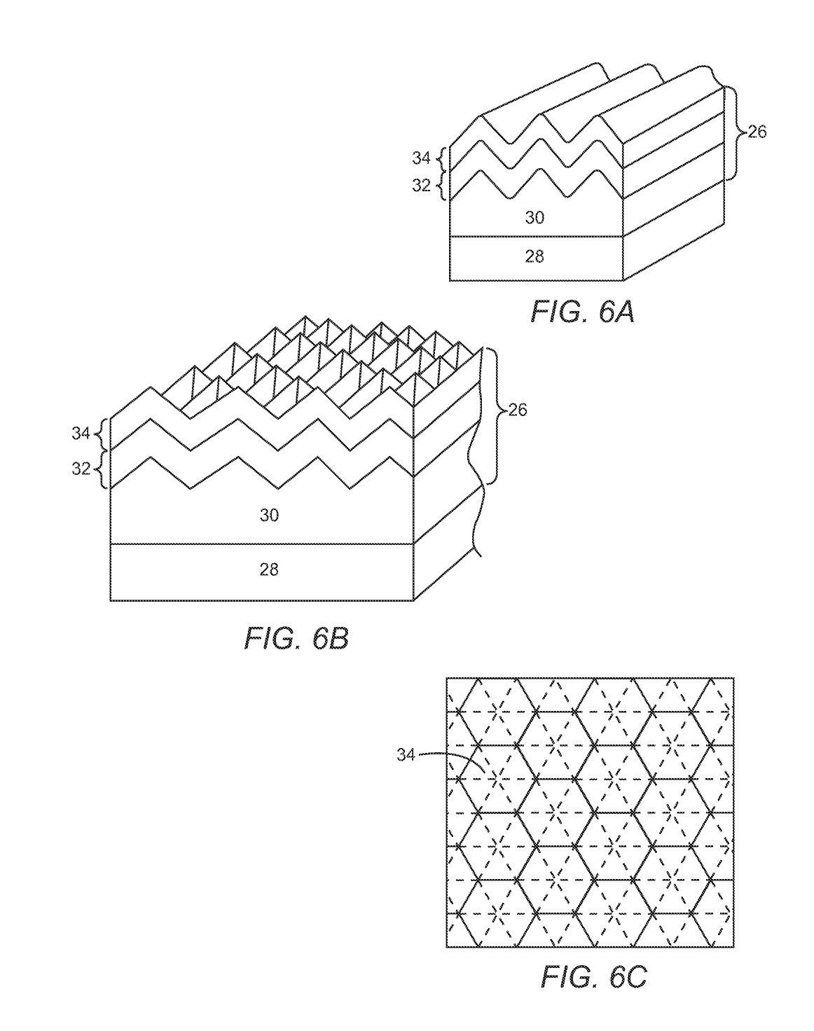

The growth facets 40 may be formed in various configurations on the n-type structure 30, and the configuration of these growth facets 40 will generally dictate the shape and overall contour of the non-planar growth surface of the n-type structure 30 as well as the active structure 32 and the p-type structure 34 that are grown thereon. For example, if each growth facet 40 is formed between an elongated ridge and an elongated valley that run along the surface of the n-type material 30, the defined contour of the non-planar growth surface of the n-type material will be corrugated. When the non-planar growth surface is corrugated, the active structure 32 and at least a portion of the p-type structure 34 may be corrugated. A perspective view of an optoelectronic device that employs a corrugated active structure 32 is illustrated in FIG. 6A.

As another example, growth facets 40 may form the different sides of a pyramidal structure, wherein the non-planar growth surface is formed of an array of substantially uniform pyramidal structures. In a GaN or other group III nitride based optoelectronic device, the pyramidal structures may take the form of a hexagonal pyramid; however, pyramids having more or less than six sides are also envisioned. When the non-planar growth surface forms an array of pyramidal structures, the active structure 32 and the p-type structure 34 will follow the defined contour of a surface of a pyramidal array. Perspective and top views of an optoelectronic device that employs an active structure 32 that follows the contour of a pyramidal array are illustrated in FIGS. 6B and 6C, respectively. For clarity, the contact layer 36, p-type contacts 38p, and n-type contacts 38n are not illustrated.

In typical optoelectronic devices 10, such as that illustrated in FIG. 1, the active structure 14 is formed over a substantially planar surface of the n-type structure 18, and as such the active structure 14 itself is substantially planar and fairly uniform. These optoelectronic devices 10 are generally designed with the intent to emit light at only a desired wavelength. Notably, non-uniformities in the active structure 14 tend to cause the wavelength of light to shift from the desired wavelength, and as such, efforts are made to keep the active structure 14 as uniform as possible to ensure light of the desired wavelength is uniformly emitted from the active structure 14.

For the present embodiments of this disclosure, the active structure 32 is non-planar and naturally bends over significant vertices, peaks, ridges, or valleys at points or along lines where the active structure 32 transitions from one planar portion to another. The wavelength of light emitted from transition portions in the active structure 32 can significantly shift with respect to the wavelength of the light emitted from the planar portions of the active structure 32 that reside over the semi-polar facets 40. This shift in the wavelength of light emitted from the active structure 32 may degrade the purity of light emitted from the optoelectronic device. Planar portions of the active structure 32 are generally those that reside over the semi-polar facets 40 of the n-type structure 30. The planar portion provides more controlled light emissions.

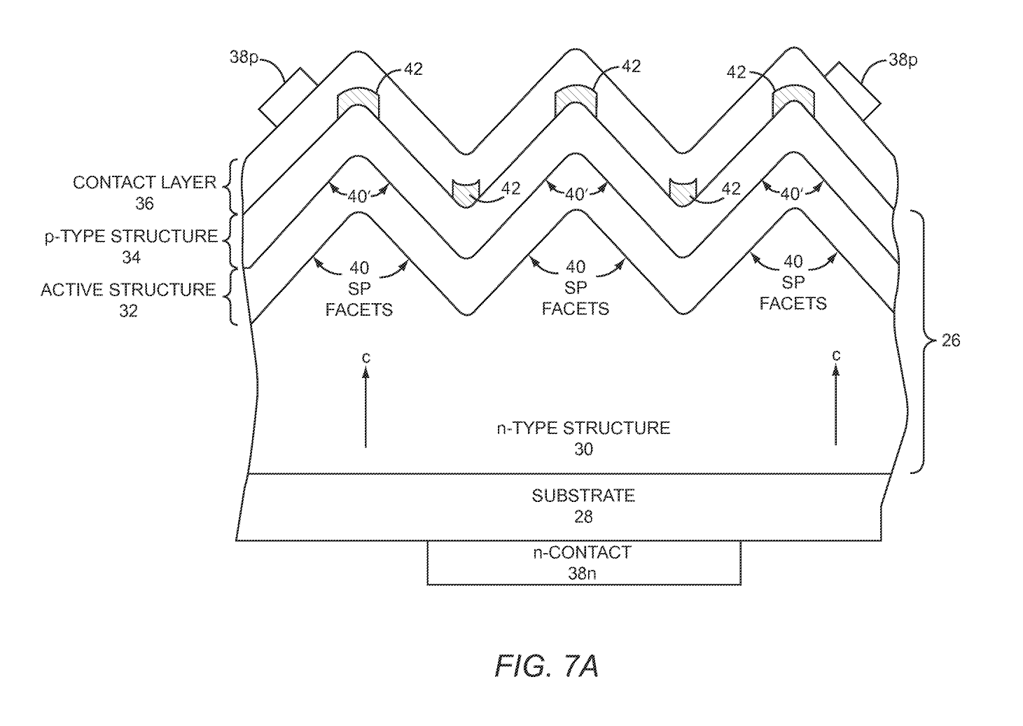

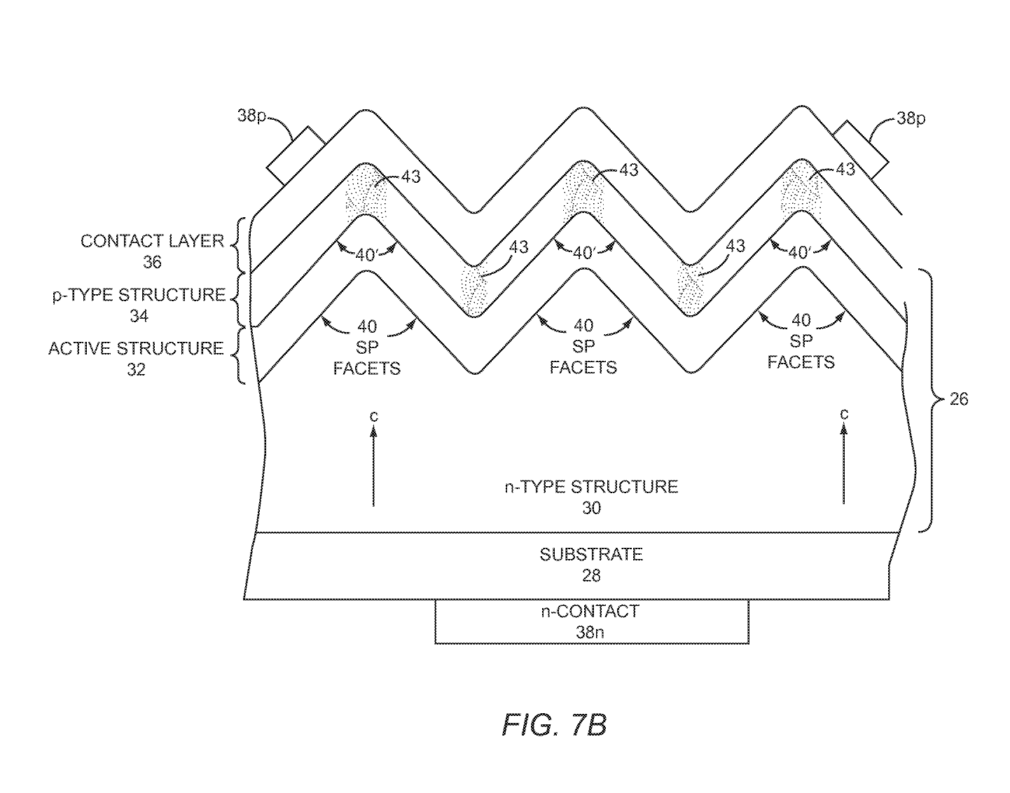

To address undesirable shifts in the wavelength of light emitted from the transition portions of the active structure 32, steps may be taken to essentially deactivate those problematic portions of the active structure 32. With reference to FIG. 7A, current masks 42 may be formed during the growth process in or on the p-type structure 34 and above the transition portions of the active structure 32 to effectively block the flow of current to the transition portions. As depicted, transition portions may be associated with the respective peaks, valleys, and the like of the active structure 32 and essentially connect adjacent planar portions residing beneath the semi-polar facets 40′ of the active structure 32. To create the current masks 42, a masking layer may be formed over the p-type structure 34, or any layer provided therein, and subsequently etched such that the current masks 42 remain. Conventional liftoff techniques may also be employed. In a corrugated configuration, such as that illustrated in FIGS. 6A and 7A, current masks 42 may be provided along and on the surfaces of the elongated ridges and valleys of the p-type structure 34. In a configuration that employs an active structure 32 that is contoured as a pyramidal array, such as that illustrated in FIGS. 6B and 6C, current masks 42 may provided on or in the p-type structure 34 at the peaks or vertices of the respective pyramids and along the ridges where adjacent sides of the pyramids come together. Notably, any coalescence fronts where common layers laterally join one another may be masked with current masks 42. These coalescence fronts may be considered as transition portions in the active structure 32 where the wavelength of emitted light is undesirably shifted. The masking layer, and thus the current masks 42, may be formed from various metallic or insulator materials, such as SiO₂, SiₓN, AlON, and Al₂O₃. The masking layer is typically a transparent, non-light absorbing material in optoelectronic devices.

As an alternative to using current masks 42, all or a portion of the transition portions of the p-type structure 34 may be intentionally damaged to prevent or otherwise significantly impede operation of the active structure 32 at the transition portions. With reference to FIG. 7B, an optoelectronic device is shown where the transition portions of the p-type structure 34 have been heavily implanted with dopants at concentrations sufficient to prevent or significantly impede operation of the active structure 32 at the transition portions. The damaged or implanted transition portions are shaded and referenced as 43. The transition portions of the p-type structure 34 may be implanted with almost any type of ion. Examples include N, Ar, Mg, Al, In, C and Fe at concentrations exceeding 1×10¹⁶cm⁻³ and even 1×10²⁰cm⁻³ in select embodiments. In certain embodiments, no heating or annealing step is provided immediately following the implantation step.

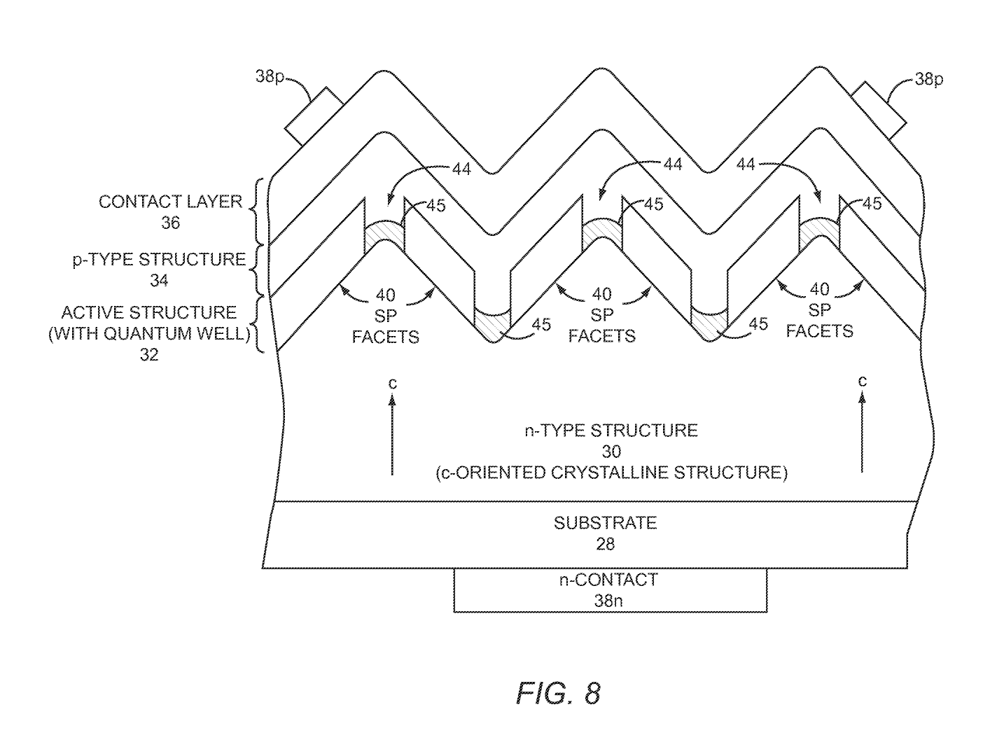

As an alternative to using current masks 42 or intentionally damaging the transition portions on the active structure 32, all or a portion of the transition portions of the active structure 32 may be removed via an appropriate etching or mechanical removal process. With reference to FIG. 8, an optoelectronic device is shown where the transition portions of the active structure 32 have been removed. The removed transitional portions leave an active structure recess 44 through all (as shown) or a portion of the active structure 32. The active structure recess 44 will generally extend at least through any layers that provide quantum wells. To prevent shorting of the n-type structure 30 and the p-type structure 34 via the active structure recesses 44, an insulator material 45 may be provided in the active structure recesses 44. Although the current masks 42 and implants shown in FIGS. 7A and 7B and the active structure recesses 44 shown in FIG. 8 are provided for all of the transition portions shown, designers may select only certain or certain types of tranₛitioₙ portions to ad_{d}rₑss by forming current masks 42, implanting, or with selective etching. For example, only the transition portions associated with peaks or ridges may be intentionally damaged through implantation, while transition portions in valleys are not damaged. Further, a combination of etching, masking, or doping techniques may be employed at the transition portions in a given structure.

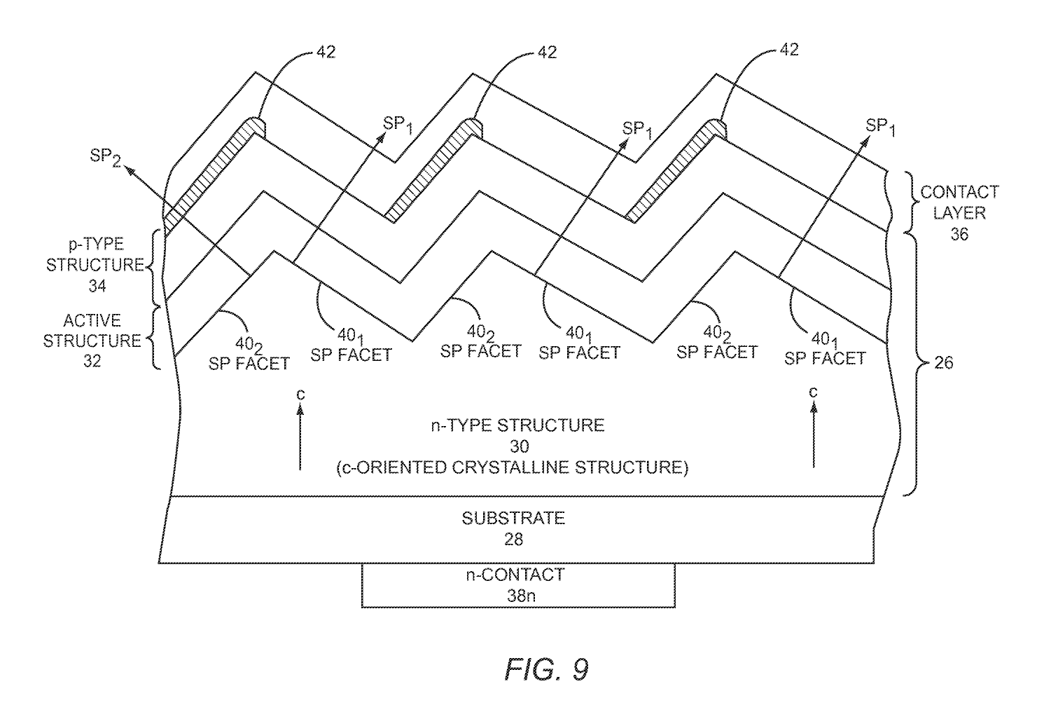

In addition to transition portions in the active structure 32, other portions of the active structure 32 may be undesirable. These undesirable portions may be masked with a current mask 42 or removed in the same manner along with any undesirable transition portion. With reference to FIG. 9, the non-planar growth surface of the n-type structure 30 is asymmetrical and includes semi-polar facets 40₁ and 40₂. Semi-polar facets 40₁ provide first semi-polar growth planes, semi-polar facets 40₂ provide second semi-polar growth planes, and the first and second semi-polar growth planes form angles, which have different magnitudes with respect to the polar c-axis. Accordingly, the different semi-polar growth planes are associated with different polarizations and different polarization magnitudes. As such, the first semi-polar portions of the active structure 32 are grown on the semi-polar facets 40₁ in a first semi-polar direction SP₁, and second semi-polar portions of the active structure 32 are grown on the semi-polar facets 40₂ in a second semi-polar direction SP_{2.} In certain configurations, the light emitted from the first semi-polar portions of the active structure 32 may emit light at a different wavelength than the light emitted from the second semi-polar portions of the active structure 32.

If light emission from one of the semi-polar portions of the active structure 32 is undesirable, the undesirable semi-polar portions can be masked with a current mask 42, removed through an etching process, or rendered effectively inactive though implantation. As shown in FIG. 9, a current mask 42 is applied on the p-type structure 34 above the second semi-polar portions of the active structure 32, while the first semi-polar portions remain intact and unmasked. The current mask 42 that is provided above the second semi-polar portion may extend over the peaks of the active structure 32 to effectively cover the transition portions associated with the peaks in the active structure 32. As such, light emissions from the second semi-polar portions and the transition portions at the peaks of the active structure 32 are essentially suppressed, while the light emissions from the first semi-polar portions remain uninhibited. Alternatively, the second semi-polar portions and any associated transition portions may be removed or implanted in such a way as to effectively render these portions inactive.

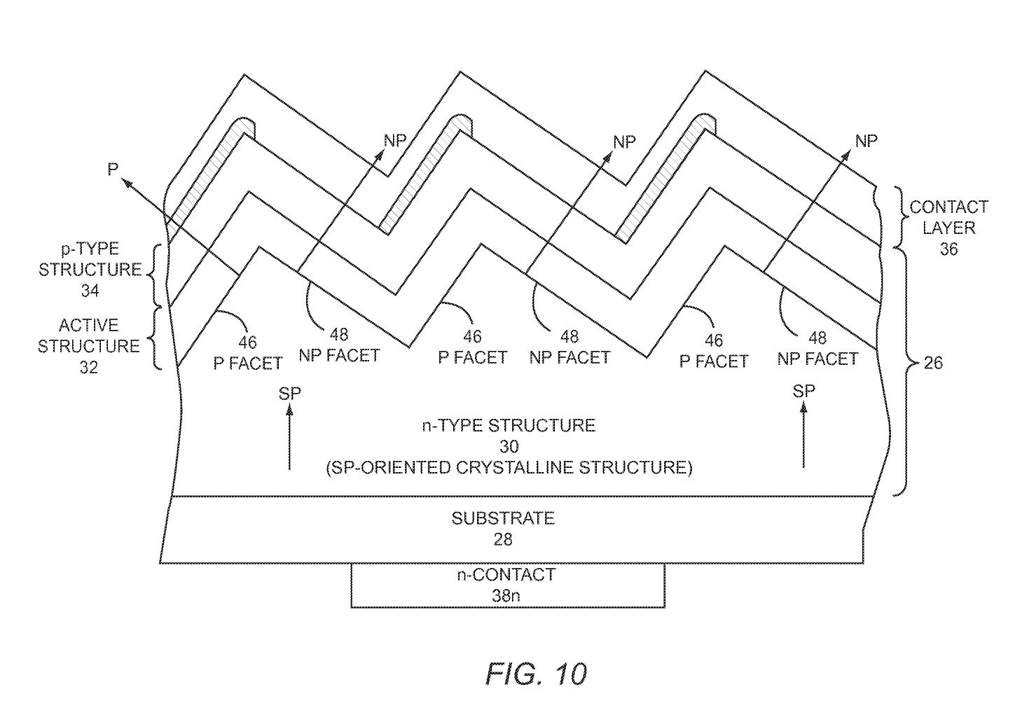

In most of the preceding examples, the n-type structure 30 is illustrated as having primarily a c-oriented (or polar) crystalline orientation. However, the concepts associated with the disclosed embodiments apply to different crystalline orientations. With reference to FIG. 10, an optoelectronic device is illustrated where the n-type structure 30 has a semi-polar crystalline orientation. As such, the n-type structure 30 is primarily grown parallel to a semi-polar direction. In this example, the non-planar growth surface on the n-type structure 30 is asymmetrical and includes polar (P) facets 46 and non-polar (NP) facets 48. The polar facets 46 provide polar growth planes and the non-polar facets 46 provide non-polar growth planes. As such, the polar portions of the active structure 32 are grown on the polar facets 46 in a corresponding polar direction P, and non-polar portions of the active structure 32 are grown on the non-polar facets 48 in a corresponding non-polar direction NP. Since the quantum wells in the polar portions of the active structure 32 are aligned with the polar c-planes, light emissions from the polar portions of the active structure 32 may not be desirable. In such cases, the polar portions of the active structure 32 may be masked with current masks 42 (as shown), removed, or implanted as described above, wherein the non-polar portions of the active structure 32 are primarily used for emitting light.

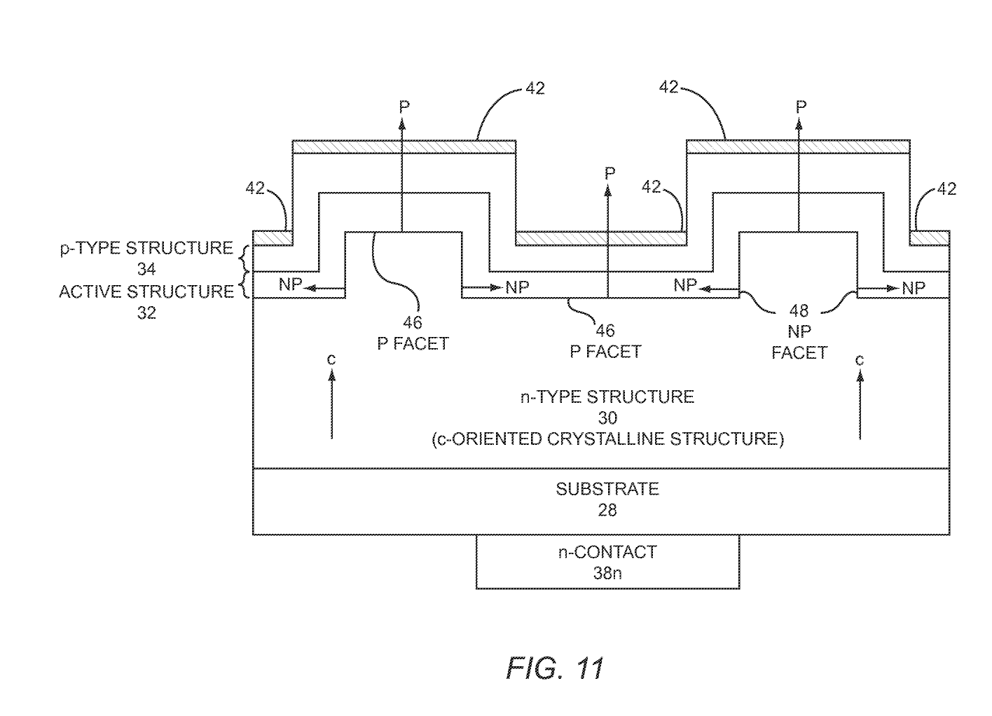

The embodiment illustrated in FIG. 11 provides for an n-type structure 30 that has a c-oriented (polar) crystalline structure. The non-planar growth surface of the n-type structure 30 is relatively symmetrical and includes polar facets 46 that are normal to the polar c-axis and non-polar facets 48 that are parallel with the polar c-axis. The polar facets 46 provide polar growth planes and the non-polar facets 48 provide non-polar growth planes. The polar portions of the active structure 32 are grown on the polar facets 46 in a corresponding polar direction P, and non-polar portions of the active structure 32 are grown on the non-polar facets 48 in a corresponding non-polar direction NP. Since the quantum wells in the polar portions of the active structure 32 are aligned with the polar c-planes, light emissions from the polar portions of the active structure 32 may not be desirable. The polar portions of the active structure 32 may be masked with current masks 42 (as shown) removed, or implanted as described above, wherein the non-polar portions of the active structure 32 are primarily used for emitting light.

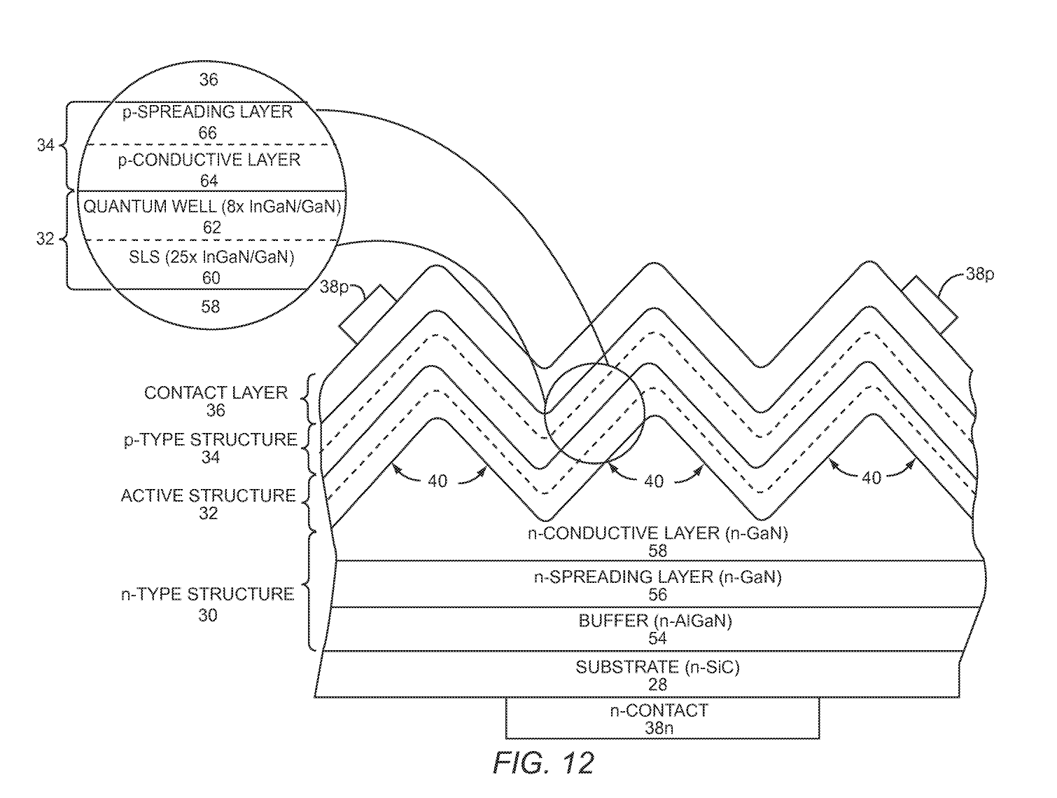

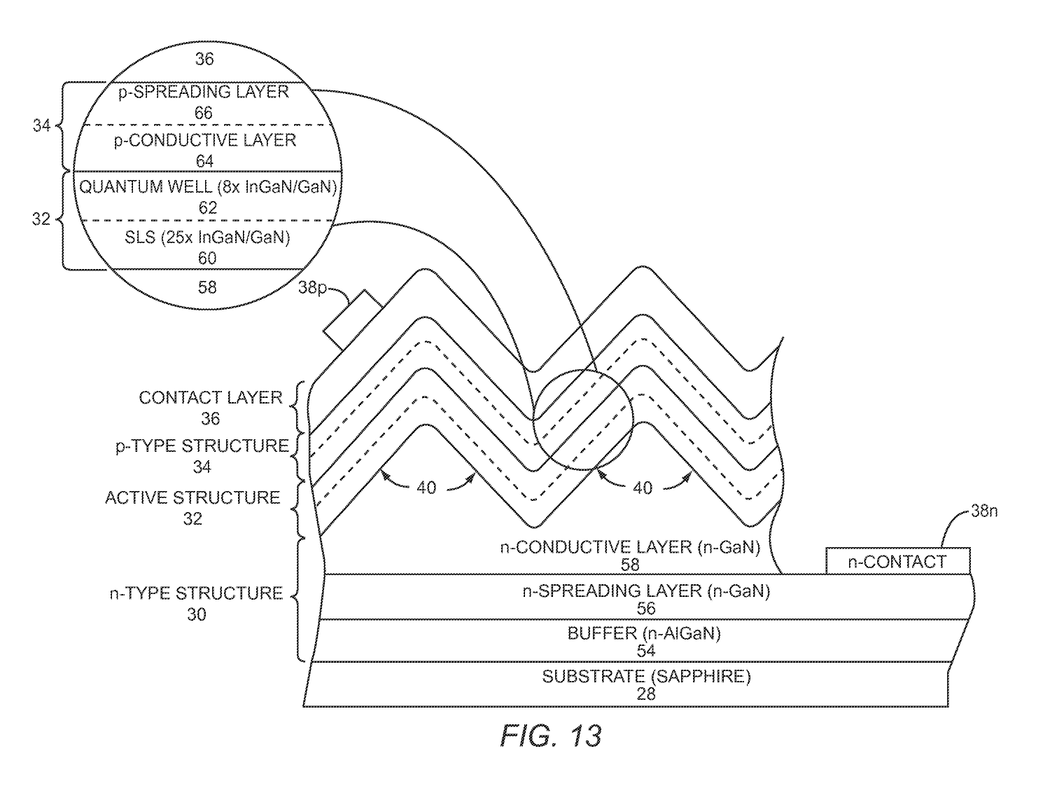

With reference to FIGS. 12 and 13, the following description provides further detail for the various n-type, active, and p-type structures 30, 32, 34 according to select embodiments of the disclosure. Again, these structures may include layers in addition to those illustrated or described. Further, additional layers may be provided between, below, or above any of these structures. Even though a given structure is labeled a p- or n-type structure, such designation does not imply that all of the layers within such a structure are intentionally doped. Those skilled in the art will recognize the ability to modify the disclosed embodiments without diverging from the concepts provided herein.

With particular reference to FIG. 12, the optoelectronic device includes a non-insulating substrate 28, which is depicted as being a 4 H or 6 H n-type silicon carbide, which has a c-oriented crystalline structure. As with the above embodiments, the overall epitaxial structure that is formed on the substrate 28 comprises gallium nitride-based semiconductor layers. In particular, the n-type structure 30 includes an AlGaN buffer 54 that is doped with an n-type dopant, GaN spreading layer that is doped with an n-type dopant (n-spreading layer 56), and a GaN conductive layer that is also doped with an n-type dopant (n-conductive layer 58). Exemplary n-type dopants include Si, Ge, Sn and O.

The buffer 54 may include various epitaxial doped layers that are sufficient to provide a conductive buffer region between the SiC-based substrate 28 and the rest of the epitaxial structure. The GaN spreading layer 56 is generally between about 500 and 5000 nm thick inclusive, and is often around 300 nm thick. The spreading layer 56 may be doped with silicon at a level of about 5×10¹⁷ to 5×10¹⁹ cm⁻³. The conductive layer 58 is preferably between about 10 and 500 angstroms thick inclusive, and is often about 80 angstroms thick. The conductive layer 58 may be doped with silicon at a level of less than about 5×10¹⁹ cm⁻³.

The active structure 32 may include a superlattice structure (SLS) 60 and a quantum well structure 62. Generally, the superlattice structure 60 includes alternating layers of In_{X}Ga_{1-X}N and In_{Y}Ga_{1-Y} N, wherein X is between 0 and 1 inclusive and X is not equal to Y. Since X is generally zero (X=0), the superlattice structure 60 is generally considered to have alternating layers of GaN and InGaN as referenced in FIGS. 12 and 13. The thickness of each of the alternating layers of InGaN is about 5-40 angstroms thick inclusive, and the thickness of each of the alternating layers of GaN is about 5-100 angstroms thick inclusive. In certain embodiments, the GaN layers are about 30 angstroms thick and the InGaN layers are about 30 angstroms thick. The superlattice structure 60 may include from about 5 to about 50 periods, wherein any given period corresponds to a GaN and InGaN pair of layers. As shown, the superlattice structure 60 comprises 25 periods. The superlattice structure 60 may be doped with an n-type impurity such as silicon at a level from about 1×10¹⁷ to about 5×10¹⁹ cm⁻³. These doping levels may be actual doping or average doping of the layers of the superlattice structure 60. The superlattice structure 60 is generally considered to provide an improved surface on which to grow a quantum well structure 62. One or more undoped GaN spacer layers (not shown) may be provided between the superlattice structure 60 and the quantum well structure 62.

The quantum well structure 62 may provide for a single quantum well, but it is preferably configured to provide for multiple quantum wells. As illustrated, the quantum well structure 62 provides for eight (8) quantum wells. The multiple InGaN quantum well layers are separated by barrier layers (not shown), and each barrier layer may be individually formed from one or more layers. The barrier layers may include In_{X}Ga_{1-X}N where 0≦X<1. A quantum well is formed in each quantum well layer, wherein the barrier layer functions to confine electrons and holes within the substantially two dimensional quantum well of each quantum well layer during operation.

The indium composition of the barrier layers is typically less than that of the quantum well layers, so that the barrier layers have a higher bandgap than quantum well layers. The barrier layers and quantum well layers are generally not intentionally doped; however, it may be desirable to dope the barrier layers if ultraviolet emission is desired. Aluminum may be added to the barrier layers to provide a better lattice match between the barrier layers and the quantum well layers, and thus improve the light emitting efficiency of the quantum well structure 62. Notably, the bandgap of the superlattice structure 60 should exceed the bandgap of the quantum well layers of the quantum well structure 62.

As an example, the barrier layers may be between about 50 and 400 angstroms thick inclusive. The quantum well layers 120 and 220 may be between about 10 and 50 angstroms thick inclusive. The thickness of the quantum well layers and percentage of indium in the quantum well layers may be varied to produce light having a desired wavelength. Typically, the percentage of indium in quantum well layers is about 25-30%; however, depending on the desired wavelength, the percentage of indium has been varied from about 5% to about 50%.

One or more layers, such as a thin AlGaN cap layer (not shown) that is undoped and formed from either GaN or AlGaN may be provided between the quantum well structure 62 and the p-type structure 34. The p-type structure 34 may include any number of layers, such as an AlGaN conductive layer that is doped with a p-type dopant (p-conductive layer 64) and a spreading layer that is doped with a p-type dopant (p-spreading layer 66). Exemplary p-type dopants include Mg, Zn, and C. The p-spreading layer 66 may form part of or reside below the contact layer 36. In one embodiment, the contact layer 36 may be formed from a transparent conductive material such as GaN, Indium Tin Oxide (ITO), or a combination thereof. ITO is a compound that provides good electrical conductivity, yet remains very transparent. This transparency allows light that is emitted from the active structure 32 to more readily escape the optoelectronic device.

In one embodiment, the p-conductive layer 64 may be between about 0 and 300 angstroms thick inclusive, and is preferably about 130 angstroms thick. The p-spreading layer 66 of p-type GaN is provided on the conductive layer 64, and is generally between 1000 and 3000 angstroms thick, and preferably about 1800 angstroms thick. Doping for the p-conductive layer 64 and p-spreading layer 66 are similar to that provided for the corresponding n-conductive layer 58 and n-spreading layer 56. As for the ohmic contacts, the p-contact 38p is provided on the contact layer 36, and the n-contact 38n is provided on the bottom of the substrate 28, respectively, for the non-insulating substrate embodiment illustrated in FIG. 12. For the embodiment in FIG. 13, the substrate 28 is made of sapphire or other insulating material. With an insulating substrate 28, current cannot readily pass through the substrate 28, and as such, the n-contact 38n is placed on the n-spreading layer 56, which may be referred to as a contact layer in such embodiments.

As seen from the above, n-type, active, and p-type structures 30, 32, 34 may have various layers. For the present disclosure, at least portions of the n-type structure 30 are grown such that an n-type surface naturally terminates into the non-planar growth surface. For the n-type structure 30 to grow in a manner creating the non-planar growth surface, conversion structures may be formed in or on one of the underlying growth surfaces within the n-type structure 30 or the substrate 28. Based on the crystalline structure and orientation of the n-type structure 30 as well as the growth characteristics of the compounds in the n-type structure 30, these conversion structures are configured to cause at least an upper portion of the n-type structure 30 to form the non-planar growth surface during fabrication.

In essence, the presence of the conversion structures interrupts or alters the normal growth process in a manner predetermined to cause the n-type structure 30 to form the non-planar growth surface. Without the conversion structures, the surface of the n-type structure 30 would be planar under typical growth conditions. As described above, the non-planar growth surface provides faceted growth planes on which the epitaxial layers of the active structure 32 are formed. Once the non-planar growth surface is formed, the epitaxial layers of the active structure 32 are grown over the faceted growth planes in a direction normal to the plane of the faceted growth planes.

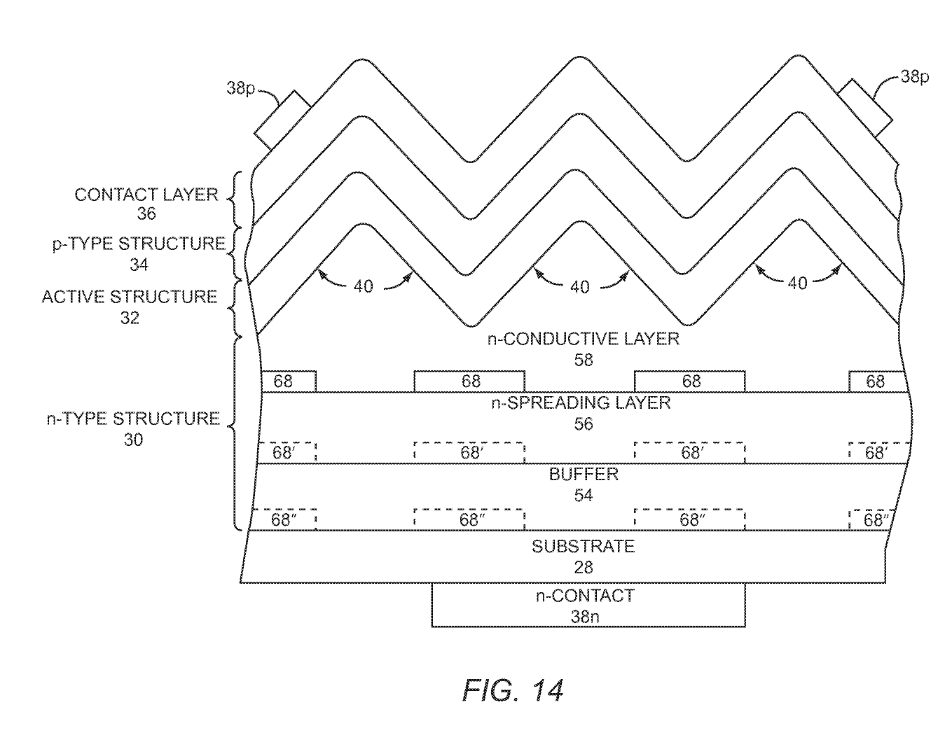

With reference to FIG. 14, conversion structures are applied to a surface of the substrate 28 or one of the layers of the n-type structure 30. As illustrated, the conversion structures are conversion masks 68, 68′, 68″, which may represent a stripe, post, or other geometry, and may be located on a planar surface of one of the n-spreading layer 56, buffer 54, or substrate 28, respectively. In such embodiments, if conversion masks 68 are provided on the n-spreading layer 56, the n-spreading layer 56 and the layers below the n-spreading layer 56 will grow in typical fashion along an orientation that is normal to the surface of the substrate 28.

For a predominately c-oriented optoelectronic device, the buffer 54 and n-spreading layer 56 will have a c-oriented crystalline structure and will grow in parallel with the polar c-axis. The conversion masks 68 are then applied to the planar surface of the n-spreading layer 56, perhaps by providing a layer of masking material and then etching away unwanted areas of the masking material to form the conversion masks 68. The masking material, and thus the conversion masks 68, may be formed from materials, such as SiO₂, SiNₓ, and Al₂O₃. The n-conductive layer 58 is then formed over the n-spreading layer 56 and around the conversion masks 68 using an overgrowth process. Given the appropriate size, shape, and orientation of the conversion masks 68 with respect to the overall crystalline orientation of the affected structures, the overgrowth process for the n-conductive layer 58 will cause the non-planar growth surface to form a desired contour on the n-conductive layer 58. For example, a corrugated non-planar growth surface as illustrated in FIG. 6A is formed when the conversion masks 68 take the form of a plurality of elongated stripes. In one embodiment, the stripes are repeated with a period that is greater than or equal to about 20 μm and perhaps about ten (10) μm. The spacing between is kept relatively small for ensured coalescence. For example, the spacing may be less than or equal to about five (5) μm and perhaps about two (2) μm. A pyramidal non-planar growth surface as illustrated in FIGS. 6B and 6C may be formed when the conversion masks 68 take the form of posts, cylinders or dots.

If conversion masks 68′ are provided on the buffer 54, the epitaxial layers in the buffer will grow in typical fashion along an orientation that is normal to the surface of the substrate 28. For a predominately c-oriented optoelectronic device, the buffer 54 will have a c-oriented crystalline structure and will grow in parallel with the polar c-axis. The conversion masks 68′ are then applied to the planar surface of the buffer 54, perhaps by providing a layer of masking material and then etching away unwanted areas of the masking material to form the conversion masks 68′. The n-spreading layer 56 is then formed over the buffer 54 and around the conversion masks 68′ using an overgrowth process. The n-conductive layer 58 is grown over the n-spreading layer 56. Given the appropriate size, shape, and orientation of the conversion masks 68′ with respect to the overall crystalline orientation of the affected structures, the overgrowth process for the n-spreading layer 56 and the growth of the n-conductive layer 58 will cause the non-planar growth surface to form on the n-conductive layer 58. If conversion masks 68″ are provided on the substrate 28, the overgrowth process starts with the buffer 54. Each successive layer of the n-type structure is formed over the conversion masks 68″ wherein the non-planar growth surface is formed on the n-conductive layer 58. Due to the overgrowth process, the valleys or dips along the non-planar surface will generally be centered above corresponding conversion masks 68, 68′, 68″.

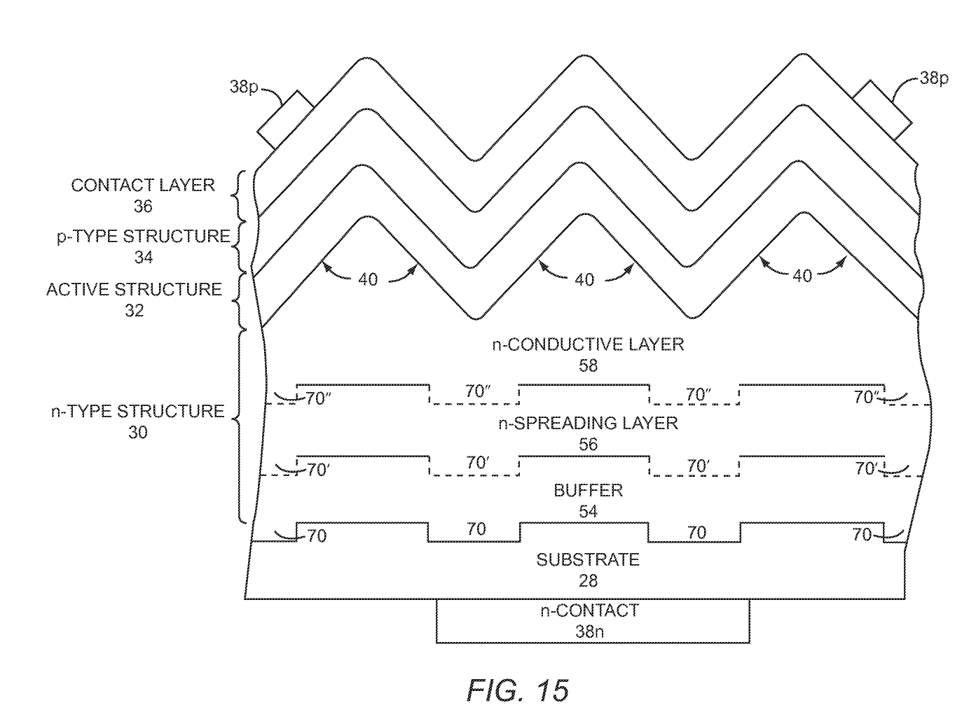

With reference to FIG. 15, conversion structures in the form of conversion recesses 70, 70′, 70″ are formed in one of the layers of the n-type structure 30 or the substrate 28. If conversion recesses 70 are provided in the substrate 28, the conversion recesses 70 cause the buffer 54 and successive layers of the n-type structure 30 to grow such that the non-planar growth surface is formed on the n-conductive layer 58. Given the appropriate size, shape, and orientation of the conversion recesses 70 with respect to the overall crystalline orientation of the affected structures, the overgrowth process for the buffer 54, n-spreading layer 56, and n-conductive layer 58 will cause the non-planar growth surface to form a desired contour on the n-conductive layer 58. For example, a corrugated non-planar growth surface as illustrated in FIG. 6A is formed when the conversion recesses 70 take the form of a plurality of elongated stripes. A pyramidal non-planar growth surface as illustrated in FIGS. 6B and 6C may be formed when the conversion recesses 70 take the form of posts, cylinders or dots. Due to the growth process, the valleys or dips along the non-planar surface will generally be centered above corresponding conversion recesses 70, 70′, 70″.

If conversion recesses 70′ are provided in the buffer 54, the conversion recesses 70′ cause the n-spreading layer 56 and successive layers of the n-type structure 30 to grow such that the non-planar growth surface is formed on the n-conductive layer 58. The buffer 54 is grown to provide a planar surface in which the conversion recesses 70′ are formed. If conversion recesses 70″ are provided in the n-spreading layer 56, the conversion recesses 70″ cause the n-conductive layer 58 of the n-type structure 30 to grow such that the non-planar growth surface is formed on the n-conductive layer 58. The buffer 54 and the n-spreading layer 56 are grown such that a planar surface in which the conversion recesses 70″ are formed is provided in the n-spreading layer 56.

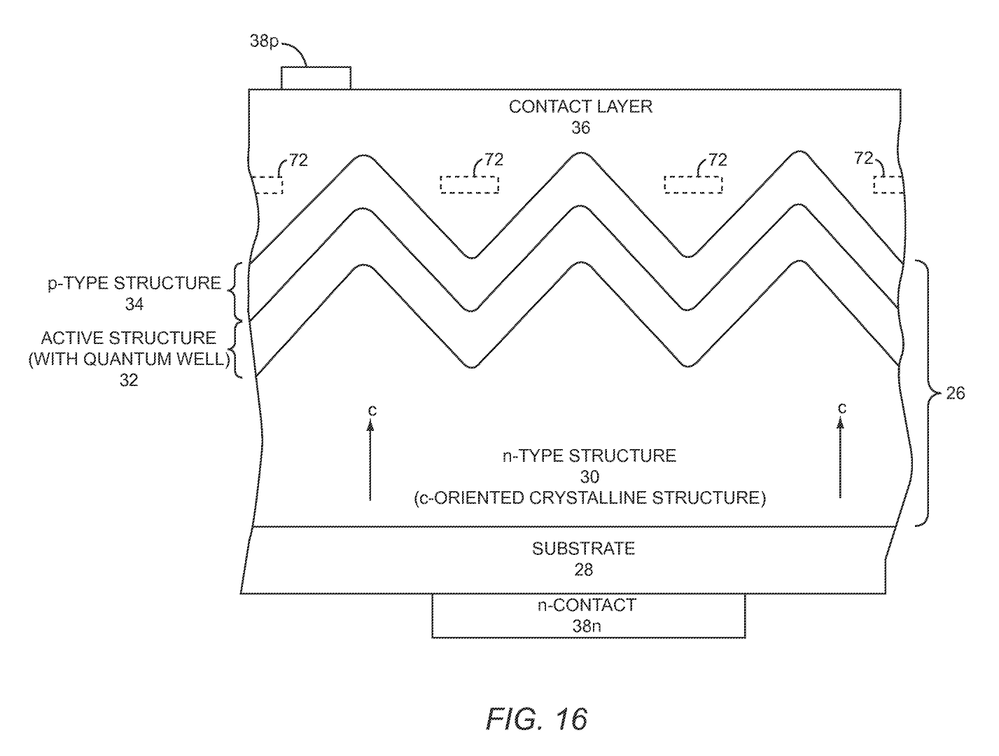

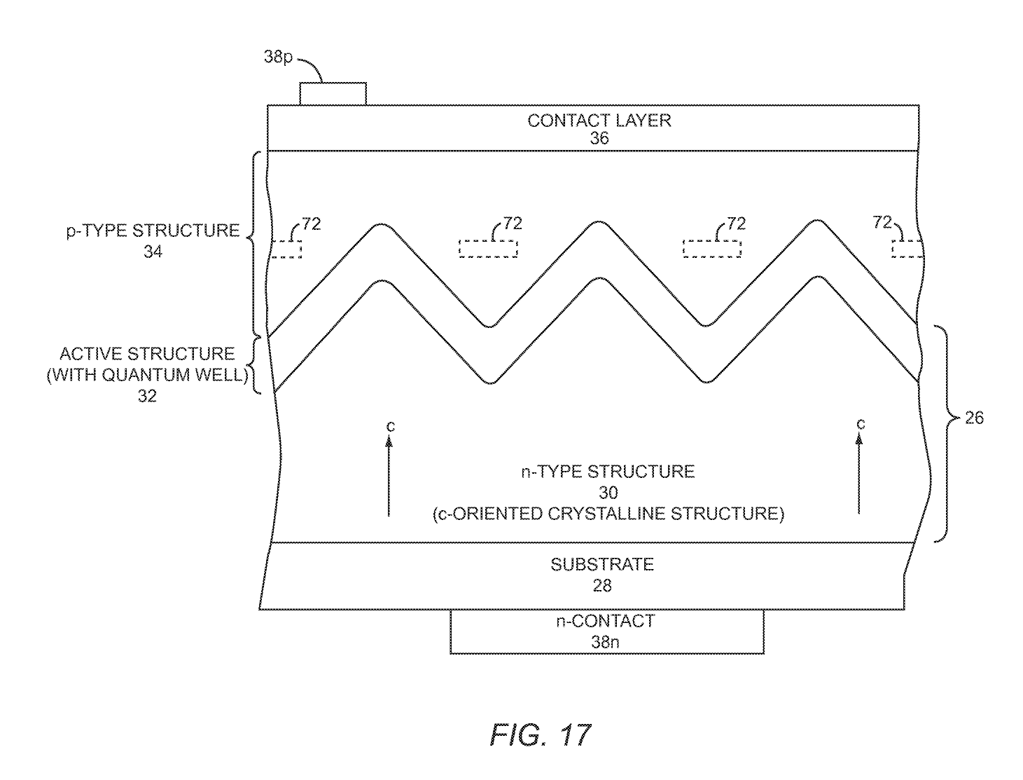

In the above embodiments, the presence of a contoured (non-planar) active structure 32 results in a device having an upper surface that is similarly contoured. However, steps may be taken to transition the epitaxial structure that resides above the active structure 32 back to a planar structure as illustrated in FIGS. 16 and 17. With particular reference to FIG. 16, the contour of the upper surface of the n-type structure 30 results in a contoured active structure 32 and a contoured p-type structure 34, wherein the upper surface of the p-type structure 34 is contoured. Through controlled growth conditions or the use of conversion structures 72, such as stripes or recesses, within or below the contact layer 36, the contact layer 36 may be grown on the contoured upper surface of the p-type structure 34 such that the upper surface of the contact layer 36 becomes planar. Alternatively, mechanical or chemical polishing may be employed to planarize the upper surface of the contact layer 36. On this planar surface of the contact layer 36, the p-contacts 38p or additional epitaxial structures may be formed in traditional fashion.

The conversion from a contoured epitaxial structure to a planar epitaxial structure may take place in virtually any region or layer. As illustrated in FIG. 17, the conversion takes place in one layer or over multiple layers within the p-type structure 34. Through controlled growth conditions or the use of conversion structures 72, such as stripes or recesses, within or below one or more layers of the p-type structure 34, the p-type structure 34 may be grown on the contoured upper surface of the active structure 32 such that the upper surface of the p-type structure 34 becomes planar. Alternatively, mechanical or chemical polishing may be employed to planarize the upper surface of the p-type structure 34. A planar contact layer 36 is grown on the planar surface of the p-type structure 34. On the planar surface provided by the contact layer 36, the p-contacts 38p or additional epitaxial structures may be formed in traditional fashion.

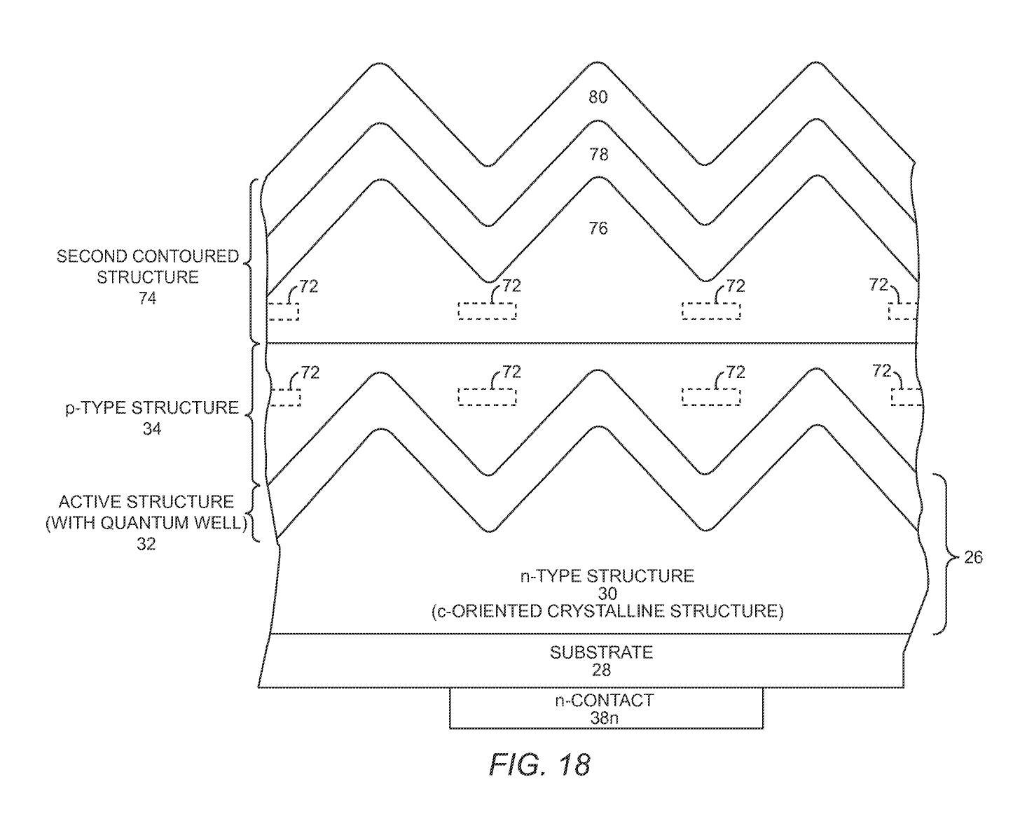

With reference to FIG. 18, a device structure may provide multiple contoured epitaxial regions that are separated by planar epitaxial regions. As illustrated, the n-type structure 30 is grown to provide the contoured surface that is described in detail above. A contoured active region 32 is grown on the contoured surface of the active structure 32 and also provides a contoured upper surface. The p-type structure 34 is grown on the contoured upper surface of the active structure 32. Notably, the p-type structure 34 is grown or otherwise processed to provide a planar upper surface on which a second contoured structure 74 is formed.

The second contoured structured 34 may be formed in the same or similar manner in which the n-type structure 30, active structure 32, and p-type structure 34 are formed. Through controlled growth conditions, the use of conversion structures 72, or a combination thereof, a lower structure 76 is grown on the planar surface of the p-type structure 34 or other epitaxial structure (not shown) to form a non-planar contoured surface. As described above, the contoured surface is formed from crystalline facets of a desired orientation relative to the overall direction of growth for the device. A contoured intermediate structure 78 may be grown on the contoured surface of the lower structure 76, and a contoured upper structure 80 may be grown on the contoured surface of the intermediate structure 78. Although not shown, a conversion may be provided to return the upper portion of the second contoured structure 74 to a substantially planar configuration as provided in FIGS. 16 and 17.

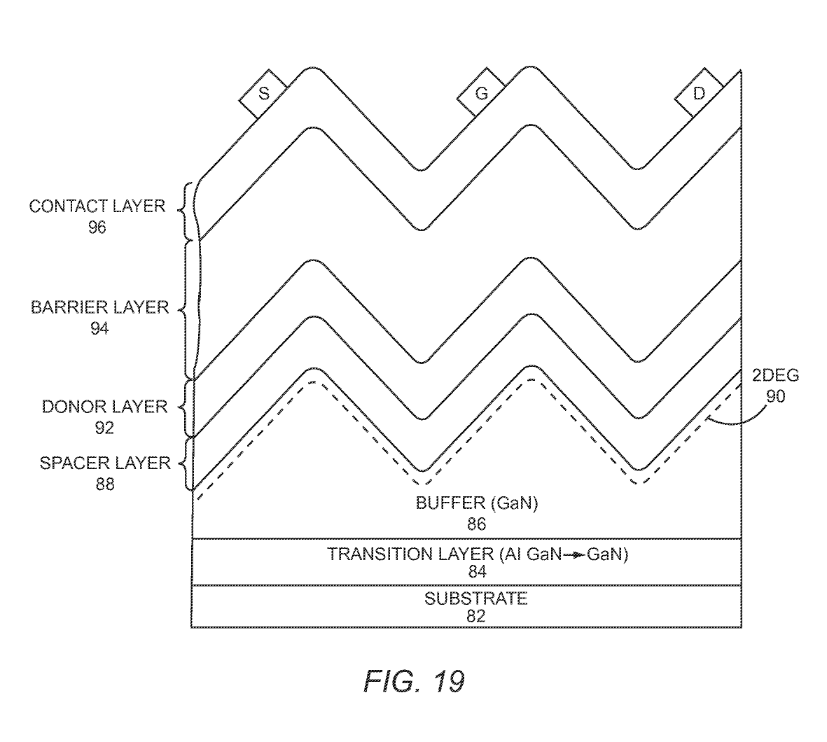

As noted, the concepts disclosed herein are applicable to various types of semiconductor devices that are affected by the inherent electric fields within the crystalline structure. With reference to FIG. 19, an exemplary high electron mobility transistor (HEMT) structure is depicted. The lower portion of the epitaxial structure of the HEMT transitions from a planar configuration to a non-planar contoured configuration, wherein the surfaces of the contoured epitaxial layers are formed by facets having a desired orientation relative to the overall grown direction or crystalline orientation of the HEMT.

In this example, a normally off HEMT may be fabricated on a substrate 82, which is formed from a semi-insulating material, such as SiC. In a GaN material system, a transition layer 84 may be grown on the substrate 82 and gradually transition from AlGaN to GaN or AlN during the growth process. The lower AlGaN portion of the transition layer 84 may provide a better interface with the substrate 82 given the lattice mismatch between GaN and SiC. The upper GaN portion provides a structurally sound transition into GaN buffer 86, which is formed over the transition layer 84.

In this example, assume that at least the buffer 86 has a c-oriented crystalline structure, which indicates that the buffer 86 is mostly grown parallel to the c-axis, and as such, will have polarized c-planes parallel to the general plane of the substrate 82. Through techniques described above, the buffer 86 is grown such that the top surface provides a non-planar growth surface, which is formed from crystalline facets and has a defined contour. Further assume for this example that the crystalline facets are formed along one or more semi-polar planes. However, as described above, the crystalline structure of the buffer 86 may have any type of orientation wherein the facets are formed along one or more planes that are associated with a polarity different from that associated with the crystalline orientation.

As illustrated, the epitaxial structure above the buffer 86 is grown over the non-planar surface in directions that are associated with a different polarity or different polarities than crystalline orientation of the buffer 86. In this example, the epitaxial structure above the buffer 86 includes a spacer layer 88, a donor (or supply) layer 92, a barrier layer 94, and a contact layer 96. In certain configurations, the contact layer 96 is not present, and the source, gate, and drain contacts S, D, and G may be recessed. Each of these layers may include one or more layers and will be grown in succession as will be appreciated by one skilled in the art. Further, additional layers may be provided between the layers that are illustrated. Source, drain, and gate contacts, S, D, and G, respectively, may be formed on the contact layer 96 along different surfaces (as illustrated) or within a single surface. The use of trenches or other isolation techniques may be used to isolation different devices, regardless of their structure.

As illustrated, the spacer layer 88 is formed from not-intentionally doped AlGaN. The donor layer 92 may be doped with silicon at a concentration between about 1×10¹⁸ cm⁻³ and 1×10¹⁹ cm⁻³. In other embodiments, such as those used for normally off devices, the donor layer 92 may be not intentionally doped or relatively lightly delta doped. An exemplary delta doping may graduate to levels between about 1×10¹²cm⁻³ and 1×10¹³cm⁻³. The barrier layer is formed from not-intentionally doped AlGaN, and the contact layer 96 is formed from non-intentionally doped GaN or AlN. Further, the transition layer 84, the buffer 86, as well as combination or portion thereof can be doped with iron to make these layers semi-insulating.

A key characteristic of a HEMT is the incorporation of a heterojunction as a channel instead of a doped region, which is used in many types of field effect transistors, such as metal oxide semiconductor field effect transistors (MOSFETs). The heterojunction is the junction between two material layers that have different band gaps. Since GaN and AlGaN have different band gaps, a heterojunction is formed between the GaN buffer 86 and the AlGaN spacer layer 88. Given the presence of this heterojunction, a two-dimensional electron gas (2DEG) 90 is formed just below the heterojunction. In particular, the 2DEG 90 is just below and follows the non-planar contour of the non-planar surface of the buffer 86. The 2DEG 90 is effectively a quantum well that confines high concentrations of electrons that drop down from the donor layer 92 in a two-dimensional space and provides a low resistivity channel for high concentrations of electrons to travel between the source contact S and drain contact D of the HEMT.

By using a non-planar 2DEG 90, portions of the 2DEG 90 can be selectively oriented along crystalline planes that are associated with desired polarizations. Orientations along crystalline planes that are associated with undesired polarizations can be avoided. For example, if the buffer 86 is c-oriented (polar oriented) and is mostly grown in a c-direction, a 2DEG 90 residing along the c-plane would experience significant piezoelectric and polarization fields. When the 2DEG 90 is non-planar and has substantial portions that are oriented along non-polar or semi-polar planes, the effects on the 2DEG 90 of the piezoelectric and polarization fields that are inherent within the c-oriented buffer 86 are reduced.

Although the 2DEG 90 forms just beneath the upper surface of the buffer 86, the spacer and donor layers 88, 92, as well as any associated layers, are considered the active structure. The buffer 86, transition layer 84, and substrate 82, as well as any associated layers, are considered the first or base structure. The epitaxial layers above the donor layer 92 and spacer layer 88 may be considered a second or upper structure. The concepts provided herein may apply to other types of field effect transistors as well as different material systems. Benefits include requiring less charge, taking on a normally off state, and reduced power consumption.

In the following claims, each plane and directions normal to the plane in a crystalline structure may be referenced as being associated with a given polarization. Available polarizations may include polar, semi-polar, and non-polar polarizations. As such, a polar plane and a direction normal to the polar plane are associated with a polar polarization. Similarly, a semi-polar plane and a direction normal to the semi-polar plane are associated with a semi-polar polarization.

Those skilled in the art will recognize improvements and modifications to the embodiments of the present disclosure. All such improvements and modifications are considered within the scope of the concepts disclosed herein and the claims that follow.

What is claimed is:

1. A semiconductor device comprising:
a first semiconductor structure having:
a first crystalline orientation that is associated with a first polarization along a primary growth direction; and
a non-planar growth surface, which is formed from a plurality of crystalline facets and provides a defined contour, wherein facets of at least a first set of the plurality of crystalline facets provide corresponding growth planes that are associated with at least one polarization that is different than the first polarization; and
a second semiconductor structure that is grown over the non-planar growth surface, wherein portions of the second semiconductor structure that are grown over the growth planes have secondary growth directions that are substantially normal to the growth planes and are associated with the at least one polarization that is different than the first polarization.

2. The semiconductor device of claim 1 wherein the first polarization is a polar polarization.

3. The semiconductor device of claim 2 wherein the at least one polarization comprises semi-polar polarization.

4. The semiconductor device of claim 2 wherein the at least one polarization comprises non-polar polarization.

5. The semiconductor device of claim 2 wherein the at least one polarization comprises a first semi-polar polarization and a second semi-polar polarization that is different than the first semi-polar polarization, wherein the growth planes of some of the facets of the at least a first set are associated with the first semi-polar polarization, and others of the facets of the at least a first set are associated with the second semi-polar polarization.

6. The semiconductor device of claim 2 wherein the at least one polarization is not a polar polarization.

7. The semiconductor device of claim 1 wherein substantially all of the plurality of crystalline facets belong to the facets of the at least a first set.

8. The semiconductor device of claim 1 wherein the first polarization is a semi-polar polarization and the at least one polarization is not a polar polarization.

9. The semiconductor device of claim 1 wherein the first polarization is a non-polar polarization and the at least one polarization is not a polar polarization.

10. The semiconductor device of claim 1 wherein the second semiconductor structure comprises a quantum well structure that provides at least one quantum well, and the at least one quantum well substantially follows the defined contour of the non-planar growth surface.

11. The semiconductor device of claim 10 wherein portions of the at least one quantum well that are over the growth planes reside in planes that are substantially parallel to the growth planes and are associated with the at least one polarization that is different than the first polarization.

12. The semiconductor device of claim 1 further comprising a third semiconductor structure that is grown over the second semiconductor structure wherein an upper surface of the second semiconductor structure substantially follows the defined contour and the third semiconductor structure is formed along the upper surface of the second semiconductor structure such that a bottom surface of the of the third semiconductor structure follows the defined contour and is formed along the upper surface of the second semiconductor structure.

13. The semiconductor device of claim 12 wherein an upper surface of the third structure is non-planar and substantially follows the defined contour.

14. The semiconductor device of claim 13 further comprising a contoured contact layer that is grown over the upper surface of the third semiconductor structure, wherein both an upper surface of the contact layer and a bottom surface of the contact layer are non-planar and substantially follow the defined contour.

15. The semiconductor device of claim 13 further comprising a contact layer that is grown over the upper surface of the third semiconductor structure, wherein a bottom surface of the contact layer is substantially non-planar and substantially follows the defined contour and the top surface of the contact layer is substantially planar and lies in a plane that is substantially normal to the primary growth direction.

16. The semiconductor device of claim 12 wherein an upper surface of the third semiconductor structure is substantially planar and lies in a plane that is substantially normal to the primary growth direction.

17. The semiconductor device of claim 16 further comprising a contact layer that is grown over the upper surface of the third semiconductor structure, wherein a bottom surface of the contact layer and an upper surface of the contact layer are substantially planar and lie in planes that are substantially normal to the primary growth direction.

18. The semiconductor device of claim 16 further comprising:
a fourth semiconductor structure having:
the first crystalline orientation that is associated with the first polarization along the primary growth direction; and
a second non-planar growth surface, which is formed from a second plurality of crystalline facets, wherein facets of at least a first set of the second plurality of crystalline facets provide corresponding growth planes that are associated with at least one polarization that is different than the first polarization; and
a fifth structure that is grown over the non-planar growth surface.

19. The semiconductor device of claim 12 wherein the first semiconductor structure is substantially doped with one of an n-type dopant and a p-type dopant, the third semiconductor structure is substantially doped with another of the n-type dopant and the p-type dopant, and the semiconductor device forms an optoelectronic device.

20. The semiconductor device of claim 12 wherein a non-planar heterojunction that follows the defined contour is formed between the first semiconductor structure and the second semiconductor structure, the second semiconductor structure comprises at least a donor layer that is capable of providing electrons to a non-planar two-dimensional electron gas region that forms in the first semiconductor structure along the heterojunction during operation, and further comprising source, gate, and drain contacts that are arranged above the donor layer such that the semiconductor device forms a high electron mobility transistor.

21. The semiconductor device of claim 1 wherein the defined contour provides a corrugated contour, and adjacent ones of the facets of the at least a first set join one another along elongated valleys or elongated ridges to provide the corrugated contour of the non-planar growth surface.

22. The semiconductor device of claim 1 wherein facets of the at least a first set are oriented to form an array of pyramidal structures, and the defined contour corresponds to an upper surface of the array of pyramidal structures.

23. The semiconductor device of claim 1 wherein the second semiconductor structure and the third semiconductor structure have the first crystalline orientation.

24. The semiconductor device of claim 1 further comprising a plurality of current masks, wherein each current mask is formed over a select portion of the second semiconductor structure to impede current flow to and thus light emission from the select portion of the second semiconductor structure during operation of the semiconductor device.

25. The semiconductor device of claim 24 wherein the select portion corresponds to at least one of a group consisting of a peak, ridge, valley, and coalescence front of the second semiconductor structure.

26. The semiconductor device of claim 24 wherein the select portion corresponds to a portion of the second semiconductor structure that reside over a growth plane of a select facet of the plurality of crystalline facets.

27. The semiconductor device of claim 1 wherein select portions of the second semiconductor structure are implanted sufficiently to significantly prevent functionality of and thus impede light emission from the select portions of the second semiconductor structure during operation of the semiconductor device.

28. The semiconductor device of claim 27 wherein the select portions correspond to at least one of a group consisting of a peak, ridge, valley, and coalescence front of the second semiconductor structure.

29. The semiconductor device of claim 27 wherein the select portions correspond to portions of the second semiconductor structure that reside over a growth plane of a select facet of the plurality of crystalline facets.

30. The semiconductor device of claim 1 further comprising a plurality of conversion structures that are provided along at least one of epitaxial layers of the first semiconductor structure and a surface of a substrate on which the first semiconductor structure is grown, wherein the presence of the plurality of conversion structures causes the first semiconductor structure to grow in such a manner as to form the non-planar growth surface.

31. The semiconductor device of claim 30 wherein the plurality of conversion structures are provided by a patterned mask structure residing on the at least one of the epitaxial layers of the first semiconductor structure and the surface of the substrate on which the first semiconductor structure is grown.

32. The semiconductor device of claim 30 wherein the plurality of conversion structures are recesses in the at least one of the epitaxial layers of the first semiconductor structure and the surface of the substrate on which the first semiconductor structure is grown.

33. The semiconductor device of claim 1 wherein the first semiconductor structure and the second semiconductor structure are predominantly formed from compounds of a group III-V material system.

34. The semiconductor device of claim 1 wherein the first semiconductor structure and the second semiconductor structure are predominantly formed from compounds of a group III-nitride material system.

35. The semiconductor device of claim 1 further comprising a substrate on which the first semiconductor structure is formed, wherein the substrate has a crystalline orientation that substantially matches that of the first semiconductor layer.

36. The semiconductor device of claim 1 wherein the first crystalline orientation is a c-orientation; the primary growth direction is along a c-axis;
the at least one polarization is a semi-polar polarization; and the first semiconductor structure and second semiconductor structure are formed predominantly from a group III-nitride material system.

37. A semiconductor device comprising:
a first semiconductor structure having:
a first crystalline orientation that is associated with a first polarization along a primary growth direction; and
a non-planar growth surface, which is formed from a plurality of crystalline facets and provides a defined contour, wherein facets of at least a first set of the plurality of crystalline facets provide corresponding growth planes that are associated with at least one polarization that is different than the first polarization;
a second semiconductor structure that is grown over the non-planar growth surface, wherein portions of the second semiconductor structure that are grown over the growth planes have secondary growth directions that are substantially normal to the growth planes and are associated with the at least one polarization that is different than the first polarization; and
a third semiconductor structure that is grown over the second semiconductor structure, wherein the first semiconductor structure is substantially implanted with one of an n-type dopant and a p-type dopant, and the third semiconductor structure is substantially implanted with another of the n-type dopant and the p-type dopant.

38. A method for fabricating a semiconductor device comprising:
providing a substrate having a first surface;
growing a first semiconductor structure over the first surface such that the first semiconductor structure has:
a first crystalline orientation that is associated with a first polarization along a primary growth direction; and
a non-planar growth surface, which is formed from a plurality of crystalline facets and provides a defined contour, wherein facets of at least a first set of the plurality of crystalline facets provide corresponding growth planes that are associated with at least one polarization that is different than the first polarization; and
growing a second semiconductor structure over the non-planar growth surface, wherein portions of the second semiconductor structure that are grown over the growth planes have secondary growth directions that are substantially normal to the growth planes and are associated with the at least one polarization that is different than the first polarization.
